(19) United States
(12) Patent Application Publication
(10) Pub. No.: US 2009/0155713 A1
(43) Pub. Date: Jun. 18, 2009

(54) RESIST COMPOSITION AND PROCESS FOR PRODUCING SAME

(75) Inventors: Toru Miyano, Kawasaki-shi (JP); Ryusaku Takahashi, Kawasaki-shi (JP); Motoko Samezawa, Kawasaki-shi (JP); Masaaki Muroi, Kawasaki-shi (JP); Koji Kanno, Kawasaki-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Tokyo Ohka Kogyo co., Ltd., Kawasaki-shi (JP)

(21) Appl. No.: 12/097,866

(22) PCT Filed: Dec. 11, 2006
(86) PCT No.: PCT/JP2006/324691

§ 371 Date: Jun. 17, 2008

(30) Foreign Application Priority Data
Dec. 21, 2005 (JP) 2005-367884

(51) Int. Cl. G03F 7/004

(52) U.S. Cl. 430/270.1

(57) ABSTRACT

A resist composition that includes an organic solvent (S) and a base material component dissolved in the organic solvent (S), wherein the organic solvent (S) contains ethyl lactate and an antioxidant, and the concentration of the antioxidant within the organic solvent (S) is 10 ppm or greater.

### TECHNICAL FIELD

The present invention relates to a resist composition and a process for producing the resist composition.

Priority is claimed on Japanese Patent Application No. 2005-367884, filed Dec. 21, 2005, the content of which is incorporated herein by reference.

### BACKGROUND ART

Lithography techniques include processes in which, for example, a resist film composed of a resist material is formed on top of a substrate, the resist film is selectively irradiated with light or some other form of radiation such as an electron beam or the like, through a mask in which a predetermined pattern has been formed, and a developing treatment is then conducted, thereby forming a resist pattern of the prescribed shape in the resist film.

Resist materials in which the exposed portions change to become soluble in the developing liquid are termed positive materials, whereas resist materials in which the exposed portions change to become insoluble in the developing liquid are termed negative materials.

In recent years, in the production of semiconductor elements and liquid crystal display elements, advances in lithography techniques have lead to rapid progress in the field of pattern miniaturization.

Typically, these miniaturization techniques involve shortening the wavelength of the exposure light source. Conventionally, ultra violet radiation typified by g-line and i-line radiation has been used, but nowadays, mass production of semiconductor elements using KrF excimer lasers and ArF excimer lasers has commenced.

Furthermore, investigation is also being conducted into radiation with even shorter wavelengths than these excimer lasers, including F₂ excimer lasers, electron beams, EUV (extreme ultra violet), and X-rays.

Resist materials are required to have specific lithography properties, including favorable sensitivity relative to the above exposure light sources, and a level of resolution that is capable of reproducing patterns of very fine dimensions.

One example of a resist material capable of satisfying these requirements is a chemically amplified resist (also referred to as a chemically amplified resist composition), which includes a base resin that displays changed alkali solubility under the action of acid, and an acid generator that generates acid upon exposure.

For example, a positive chemically amplified resist includes a resin that exhibits increased alkali solubility under the action of acid as a base resin, and an acid generator, and during resist pattern formation, when acid is generated from the acid generator by exposure, the exposed portions become alkali-soluble.

Until recently, polyhydroxystyrene (PHS) or derivative resins thereof in which the hydroxyl groups have been protected with acid-dissociable, dissolution-inhibiting groups (PHS-based resins), which exhibit high transparency relative to a KrF excimer laser (248 nm), have been used as the base resin of chemically amplified resists. However because PHS-based resins contain aromatic rings such as benzene rings, their transparency is inadequate for light with wavelengths shorter than 248 nm, such as light of 193 nm. Accordingly, chemically amplified resists that use a PHS-based resin as the base resin component suffer from low levels of resolution in processes that use light of 193 nm.

As a result, resins that contain structural units derived from (meth)acrylate esters within the principal chain (acrylic resins) are now widely used as the base resins for resists (also referred to as resist compositions) that use ArF excimer laser lithography or the like, as they offer excellent transparency in the vicinity of 193 nm (see Patent Reference 1).

Furthermore, ethyl lactate and the like are used as solvents for these resist compositions.

[Patent Reference 1]

Japanese Unexamined Patent Application, First Publication No. 2003-241385

### DISCLOSURE OF INVENTION

### Problems to be Solved by the Invention

However, with conventional resist compositions, and particularly those dissolved in an organic solvent that includes ethyl lactate, if a resist pattern is formed following storage of the resist composition for a certain period of time, then a problems arises in that the dimensions of the resist pattern vary considerably over time. Accordingly, for such resist compositions, improvements in the dimensional stability of the resist pattern are desirable.

The present invention takes the above circumstances into consideration, with an object of providing a resist composition dissolved in an organic solvent that includes ethyl lactate, wherein dimensional variation in the resist pattern due to storage of the resist composition is inhibited, as well as providing a process for producing such a resist composition.

### Means for Solving the Problems

In order to achieve the above object, the inventors of the present invention propose the following aspects.

In other words, a first aspect of the present invention is a resist composition that includes an organic solvent (S) and a base material component dissolved in the organic solvent (S), wherein the organic solvent (S) contains ethyl lactate and an antioxidant, and the concentration of the antioxidant within the organic solvent (S) is 10 ppm or greater.

Furthermore, a second aspect of the present invention is a process for producing a resist composition that includes the steps of: preparing an organic solvent (S) using ethyl lactate that contains an antioxidant, so that the concentration of the antioxidant within the organic solvent (S) is 10 ppm or greater, and dissolving a base material component in the organic solvent (S).

### EFFECTS OF THE INVENTION

According to the present invention, a resist composition dissolved in an organic solvent that includes ethyl lactate can be provided for which dimensional variation in the resist pattern due to storage of the resist composition is inhibited, and a process for producing such a resist composition is also provided.

### BEST MODE FOR CARRYING OUT THE INVENTION

### Resist Composition

A resist composition of the present invention is prepared by dissolving a base material component in an organic solvent (S) hereafter also referred to as the component (S)).

In terms of the effects achieved for the present invention, the resist composition is preferably a chemically amplified resist composition.

Within the scope of the claims and the description of the present invention, the term “base material component” describes a material with a resist film-forming capability. Any of the multitude of conventional materials used as resin components within known resist compositions can be used as the base material component. In the case of a preferred chemically amplified resist composition of the present invention, the base material component used is preferably a resin component (A) (hereafter referred to as the component (A)) that displays changed alkali solubility under the action of acid.

Furthermore, in the case of a chemically amplified resist composition, an acid generator component (B) (hereafter referred to as the component (B)) that generates acid upon exposure is used in combination with the base material component (A). A nitrogen-containing organic compound (D) and other optional components may also be used.

A more detailed description of each of these components is provided below.

### <Component (A)>

There are no particular restrictions on the component (A), provided it is a resin component that displays changed alkali solubility under the action of acid, and one or more of the alkali-soluble resins, or resins that can be converted to an alkali-soluble state, that have already been proposed as the base resins for chemically amplified resists can be used. The former case describes a so-called negative resist composition, and the latter case describes a so-called positive resist composition.

In the case of a negative composition, a cross-linker is added to the resist composition together with the alkali-soluble resin and the component (B). Then, during resist pattern formation, when acid is generated from the component (B) by exposure, the action of this acid causes cross-linking to occur between the alkali-soluble resin and the cross-linker, causing the composition to become alkali-insoluble.

As the alkali-soluble resin, resins containing structural units derived from at least one compound selected from amongst α-(hydroxyalkyl) acrylic acids and lower alkyl esters of α-hydroxyalkyl) acrylic acids enable the formation of resist patterns with minimal swelling, and are consequently preferred. An α-(hydroxyalkyl) acrylic acid refers to either one of, or both, an acrylic acid in which a hydrogen atom is bonded to the α-position carbon atom to which the carboxyl group is bonded, and an α-hydroxyalkylacrylic acid in which a hydroxyalkyl group is bonded to the α-position carbon atom.

Furthermore, as the cross-linker, typically, the use of an amino-based cross-linker such as a glycoluril containing a methylol group or alkoxymethyl group, and particularly a methoxymethyl group or butoxymethyl group, enables the formation of a resist pattern with minimal swelling, and is consequently preferred. The blend quantity of the cross-linker is preferably within a range from 1 to 50 parts by weight per 100 parts by weight of the alkali-soluble resin.

In the case of a positive composition, the component (A) is an alkali-insoluble compound containing so-called acid-dissociable, dissolution-inhibiting groups, and when acid is generated from the component (B) upon exposure, this acid causes the acid-dissociable, dissolution-inhibiting groups to dissociate, causing the component (A) to become alkali-soluble.

Consequently, during resist pattern formation, by selectively exposing the resist composition applied to the surface of the substrate, the alkali solubility of the exposed portions is increased, meaning alkali developing can then be conducted.

In the present invention, a positive resist composition is preferred.

Examples of components (A) that can be used favorably within positive compositions include polyhydroxystyrene-based resins, and acrylate ester-based resins.

Components (A) that can be used favorably in chemically amplified resist compositions are described below using examples of resin components that can be used favorably within lithography processes that use an ArF excimer laser.

A component (A) that can be used favorably with an ArF excimer laser preferably includes a copolymer containing a structural unit (a1) derived from an acrylate ester that contains an acid-dissociable, dissolution-inhibiting group, and a structural unit (a2) derived from an acrylate ester that contains a lactone-containing cyclic group.

Furthermore, the copolymer is preferably a copolymer (A1) that also contains a structural unit (a3) derived from an acrylate ester that contains a polar group-containing aliphatic hydrocarbon group. In other words, the copolymer (A1) includes the structural unit (a1), the structural unit (a2), and the structural unit (a3).

Furthermore, the component (A) may include other resins besides the copolymer (A1), or may be formed solely from the copolymer (A1).

The proportion of the copolymer (A1) within the component (A) is preferably at least 50% by weight, is even more preferably within a range from 80 to 100% by weight, and is most preferably 100% by weight.

In the component (A), either a single copolymer (A1) may be used alone, or a combination of two or more different copolymers may be used.

In this description, the expression “structural unit derived from an acrylate ester” refers to a structural unit that is formed by the cleavage of the ethylenic double bond of an acrylate ester.

The term “acrylate ester” is deemed to include not only the acrylate ester, in which a hydrogen atom is bonded to the α-position carbon atom, but also structures in which a substituent group (an atom or group other than a hydrogen atom) is bonded to the α-position carbon atom. Examples of this substituent group include a halogen atom, a lower alkyl group, or a halogenated lower alkyl group. Examples of the halogen atom include a fluorine atom, chlorine atom, bromine atom or iodine atom, and a fluorine atom is particularly desirable.

Unless stated otherwise, the “α-position” (α-position carbon atom) of a structural unit derived from an acrylate ester refers to the carbon atom to which the carbonyl group is bonded.

An “alkyl group”, unless stated otherwise, includes straight-chain, branched-chain, and cyclic monovalent saturated hydrocarbon groups.

A “lower alkyl group” refers to an alkyl group of 1 to 5 carbon atoms.

A “halogenated lower alkyl group” is a group in which portion of, or all of, the hydrogen atoms of an aforementioned lower alkyl group have been substituted with a halogen atom. Examples of the halogen atom include a fluorine atom, chlorine atom, bromine atom or iodine atom, and a fluorine atom is particularly desirable.

In the acrylate ester, specific examples of lower alkyl groups that may act as the α-position substituent group include straight-chain and branched lower alkyl groups such as a methyl group, ethyl group, propyl group, isopropyl group, n-butyl group, isobutyl group, tert-butyl group, pentyl group, isopentyl group and neopentyl group. In the present invention, the atom or group bonded to the α-position of the acrylate ester is preferably a hydrogen atom, halogen atom, lower alkyl group or halogenated lower alkyl group, is even more preferably a hydrogen atom, fluorine atom, lower alkyl group or fluorinated lower alkyl group, and from the viewpoint of industrial availability, is most preferably a hydrogen atom or a methyl group.

Structural Unit (a1)

The structural unit (a1) is a structural unit derived from an acrylate ester that contains an acid-dissociable, dissolution-inhibiting group.

The acid-dissociable, dissolution-inhibiting group in the structural unit (a1) can use any of the groups that have been proposed as acid-dissociable, dissolution-inhibiting groups for the base resins of chemically amplified resists, provided the group has an alkali dissolution-inhibiting effect that renders the entire copolymer (A1) alkali-insoluble prior to dissociation, and then following dissociation, causes the entire copolymer (A1) to change to an alkali-soluble state. Generally, groups that form either a cyclic or chain-like tertiary alkyl ester, or a cyclic or chain-like alkoxyalkyl ester with the carboxyl group of the (meth)acrylate acid are the most widely known. In this description, the term “(meth) acrylic acid” is a generic term that describes either one of, or both, acrylic acid and methacrylic acid. Furthermore, the term “(meth)acrylate ester” describes either one of, or both, the acrylate ester in which a hydrogen atom is bonded to the α-position, and the methacrylate ester in which a methyl group is bonded to the opposition.

Here, a tertiary alkyl ester describes a structure in which an ester is formed by substituting the hydrogen atom of a carboxyl group with a chain-like or cyclic alkyl group, and a tertiary carbon atom within the chain-like or cyclic alkyl group is bonded to the oxygen atom at the terminal of the carbonyloxy group (—C(O)—O—). In this tertiary alkyl ester, the action of acid causes cleavage of the bond between the oxygen atom and the tertiary carbon atom.

The chain-like or cyclic alkyl group may contain a substituent group.

Hereafter, for the sake of simplicity, a group that exhibits acid dissociability as a result of the formation of a tertiary alkyl ester at a carboxyl group is referred to as a “tertiary alkyl ester-based acid-dissociable, dissolution-inhibiting group”.

Furthermore, a cyclic or chain-like alkoxyalkyl ester describes a structure in which an ester is formed by substituting the hydrogen atom of a carboxyl group with an alkoxyalkyl group, wherein the alkoxyalkyl group is bonded to the oxygen atom at the terminal of the carbonyloxy group (—C(O)—O—). In this alkoxyalkyl ester, the action of acid causes cleavage of the bond between the oxygen atom and the alkoxyalkyl group.

As the structural unit (a1), the use of one or more structural units selected from the group consisting of structural units represented by a general formula (a1-0-1) shown below and structural units represented by a general formula (a1-0-2) shown below is preferred.

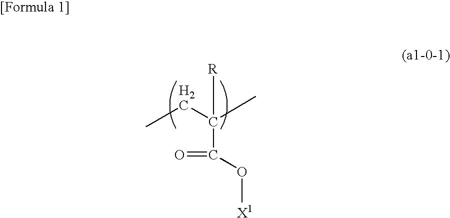

(wherein, R represents a hydrogen atom, halogen atom, lower alkyl group, or halogenated lower alkyl group; and X¹ represents an acid-dissociable, dissolution-inhibiting group)

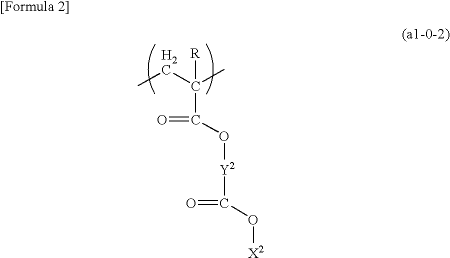

(wherein, R represents a hydrogen atom, halogen atom, lower alkyl group, or halogenated lower alkyl group; X² represents an acid-dissociable, dissolution-inhibiting group; and Y² represents an alkylene group or aliphatic cyclic group)

In the general formula (a1-0-1), the halogen atom, lower alkyl group or halogenated lower alkyl group represented by R are as described above for the halogen atom, lower alkyl group or halogenated lower alkyl group that may be bonded to the α-position of an acrylate ester.

There are no particular restrictions on the group X¹, provided it functions as an acid-dissociable, dissolution-inhibiting group, and suitable examples include an alkoxyalkyl group or a tertiary alkyl ester-based acid-dissociable, dissolution-inhibiting group, although a tertiary alkyl ester-based acid-dissociable, dissolution-inhibiting group is preferred. Examples of suitable tertiary alkyl ester-based acid-dissociable, dissolution-inhibiting groups include aliphatic branched-chain acid-dissociable, dissolution-inhibiting groups and acid-dissociable, dissolution-inhibiting groups that contain an aliphatic cyclic group.

In this description, the term “aliphatic” is a relative concept used in relation to the term “aromatic”, and defines a group or compound or the like that contains no aromaticity. The term “aliphatic cyclic group” describes a monocyclic group or polycyclic group that contains no aromaticity.

The “aliphatic cyclic group” within the structural unit (a1) may either contain, or not contain, substituent groups. Examples of suitable substituent groups include lower alkyl groups of 1 to 5 carbon atoms, a fluorine atom, fluorinated lower alkyl groups of 1 to 5 carbon atoms that have undergone substitution with a fluorine atom, and an oxygen atom (═O) or the like.

The basic ring structure of the “aliphatic cyclic group” excluding substituent groups is not restricted to groups formed solely from carbon and hydrogen (hydrocarbon groups), although a hydrocarbon group is preferred. Furthermore, the “hydrocarbon group” may be either saturated or unsaturated, but is usually saturated. The group is preferably a polycyclic group.

Specific examples of this type of aliphatic cyclic group include groups in which one or more hydrogen atoms have been removed from a monocycloalkane or a polycycloalkane such as a bicycloalkane, tricycloalkane or tetracycloalkane, which may, or may not, be substituted with a lower alkyl group, fluorine atom or a fluoroalkyl group. Specific examples of suitable groups include groups in which one or more hydrogen atoms have been removed from a monocycloalkane such as cyclopentane or cyclohexane, or a polycycloalkane such as adamantane, norbornane, isobornane, tricyclodecane or tetracyclododecane.

Specific examples of suitable aliphatic branched-chain acid-dissociable, dissolution-inhibiting groups include a tert-butyl group and a tert-amyl group.

Furthermore, examples of acid-dissociable, dissolution-inhibiting groups that contain an aliphatic cyclic group include groups that contain a tertiary carbon atom within the ring skeleton of a cyclic alkyl group, and specific examples include a 2-methyl-2-adamantyl group and 2-ethyl-2-adamantyl group. Other possible groups include those that contain an aliphatic cyclic group such as an adamantyl group, and a branched-chain alkylene group that contains a tertiary carbon atom and is bonded to the aliphatic cyclic group, such as the group shown within the structural unit represented by a general formula shown below.

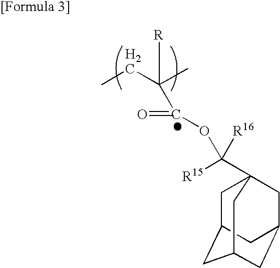

[wherein, R represents a hydrogen atom, halogen atom, lower alkyl group, or halogenated lower alkyl group, and R¹⁵ and R¹⁶ represent alkyl groups (which may be either straight-chain or branched-chain groups, and preferably contain from 1 to 5 carbon atoms)]

The halogen atom, lower alkyl group or halogenated lower alkyl group represented by R in the above formula are as described above for the halogen atom, lower alkyl group or halogenated lower alkyl group that may be bonded to the α-position of an acrylate ester.

Furthermore, the above alkoxyalkyl group is preferably a group represented by a general formula shown below.

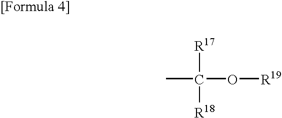

(wherein, R¹⁷ and R¹⁸ each represent, independently, a straight-chain or branched alkyl group or a hydrogen atom, and R¹⁹ represents a straight-chain, branched or cyclic alkyl group. Furthermore, R¹⁷ and R¹⁹ may be bonded together at their respective terminals to form a ring)

The number of carbon atoms within an alkyl group of the groups R¹⁷ and R¹⁸ is preferably from 1 to 15, and the group may be either a straight-chain or branched-chain group, although an ethyl group or methyl group is preferred, and a methyl group is the most desirable. Those cases in which one of the groups R¹⁷ and R¹⁸ is a hydrogen atom and the other is a methyl group are particularly desirable.

R¹⁹ is a straight-chain, branched or cyclic alkyl group, the number of carbon atoms within the group is preferably from 1 to 15, and the group may be a straight-chain, branched-chain or cyclic group.

In those cases where R¹⁹ is a straight-chain or branched-chain group, the number of carbon atoms is preferably from 1 to 5, an ethyl group or methyl group is preferred, and an ethyl group is particularly desirable.

In those cases where R¹⁹ is a cyclic group, the number of carbon atoms is preferably from 4 to 15, even more preferably from 4 to 12, and is most preferably from 5 to 10. Specific examples of this type of cyclic group include groups in which one or more hydrogen atoms have been removed from a monocycloalkane or a polycycloalkane such as a bicycloalkane, tricycloalkane or tetracycloalkane, which may, or may not, be substituted with a fluorine atom or a fluoroalkyl group. Specific examples of suitable groups include groups in which one or more hydrogen atoms have been removed from a monocycloalkane such as cyclopentane or cyclohexane, or a polycycloalkane such as adamantane, norbornane, isobornane, tricyclodecane or tetracyclododecane. Of these, groups in which one or more hydrogen atoms have been removed from adamantane are particularly desirable.

Furthermore, in the above formula, R¹⁷ and R¹⁹ may each represent, independently, an alkylene group of 1 to 5 carbon atoms, wherein the terminal of R¹⁹ and the terminal of R¹⁷ are bonded together.

In such cases, a cyclic group is formed from the groups R¹⁷ and R¹⁹, the oxygen atom bonded to R¹⁹, and the carbon atom that is bonded to this oxygen atom and the group R¹⁷. This type of cyclic group is preferably a 4- to 7-membered ring, and 4- to 6-membered rings are even more desirable. Specific examples of these cyclic groups include a tetrahydropyranyl group and a tetrahydrofuranyl group.

In the general formula (a1-0-2), the halogen atom, lower alkyl group or halogenated lower alkyl group represented by R are as described above for the halogen atom, lower alkyl group or halogenated lower alkyl group that may be bonded to the α-position of an acrylate ester.

X² is as described for X¹ in the formula (a1-0-1).

Y² is preferably an alkylene group of 1 to 4 carbon atoms or a bivalent aliphatic cyclic group.

In those cases where Y² is a bivalent aliphatic cyclic group, with the exception of using groups in which two or more hydrogen atoms have been removed, the same groups as those described within the section relating to “aliphatic cyclic groups” in the structural unit (a1) can be used.

Specific examples of the structural unit (a1) include the structural units represented by general formulas (a1-1) to (a1-4) shown below.

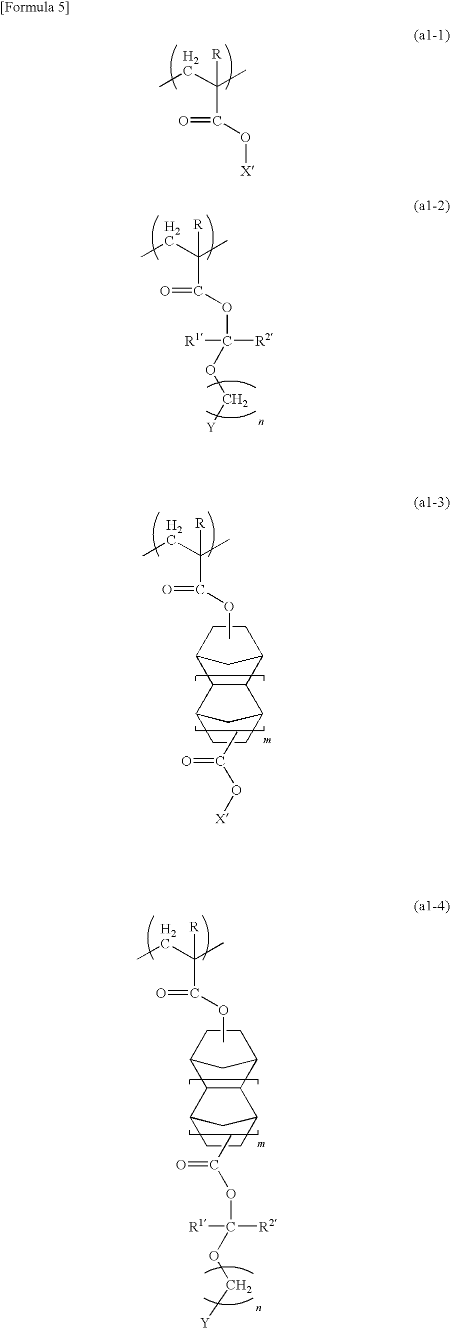

[In the above formulas, X′ represents a tertiary alkyl ester-based acid-dissociable, dissolution-inhibiting group; Y represents a lower alkyl group of 1 to 5 carbon atoms or an aliphatic cyclic group; n represents an integer from 0 to 3; m represents either 0 or 1; R represents a hydrogen atom, halogen atom, lower alkyl group or halogenated lower alkyl group; and R^{1′} and R^{2′} each represent, independently, a hydrogen atom or a lower alkyl group of 1 to 5 carbon atoms.]

The halogen atom, lower alkyl group or halogenated lower alkyl group represented by R in the above general formulas (a1-1) to (a1-4) are as described above for the halogen atom, lower alkyl group or halogenated lower alkyl group that may be bonded to the α-position of an acrylate ester.

At least one of the groups R^{1′} and R^{2′} is preferably a hydrogen atom, and units in which both R^{1′} and R^{2′} are hydrogen atoms are even more preferred.

n is preferably either 0 or 1.

X′ represents the same tertiary alkyl ester-based acid-dissociable, dissolution-inhibiting groups as those described above in relation to the group X¹.

Examples of the aliphatic cyclic group represented by Y include the same groups as those described within the section relating to “aliphatic cyclic groups” in the structural unit (a1).

Specific examples of the structural units represented by the above general formulas (a1-1) to (a1-4) are shown below.

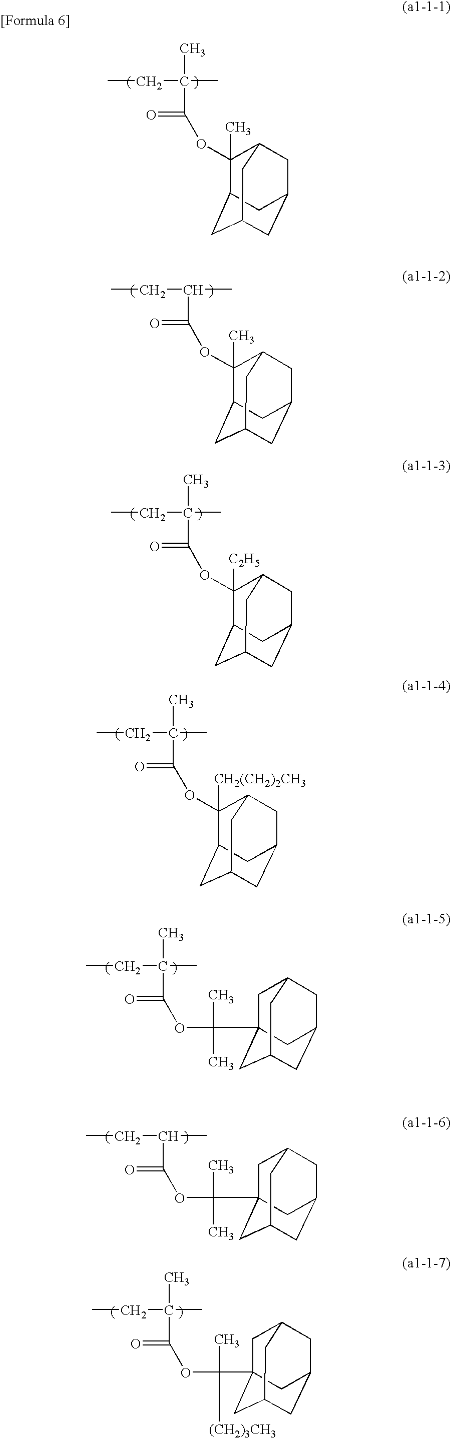

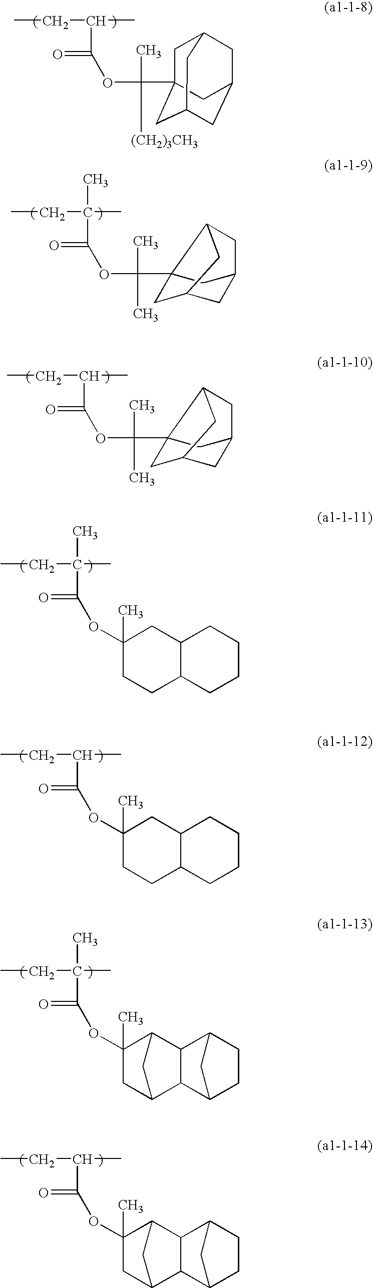

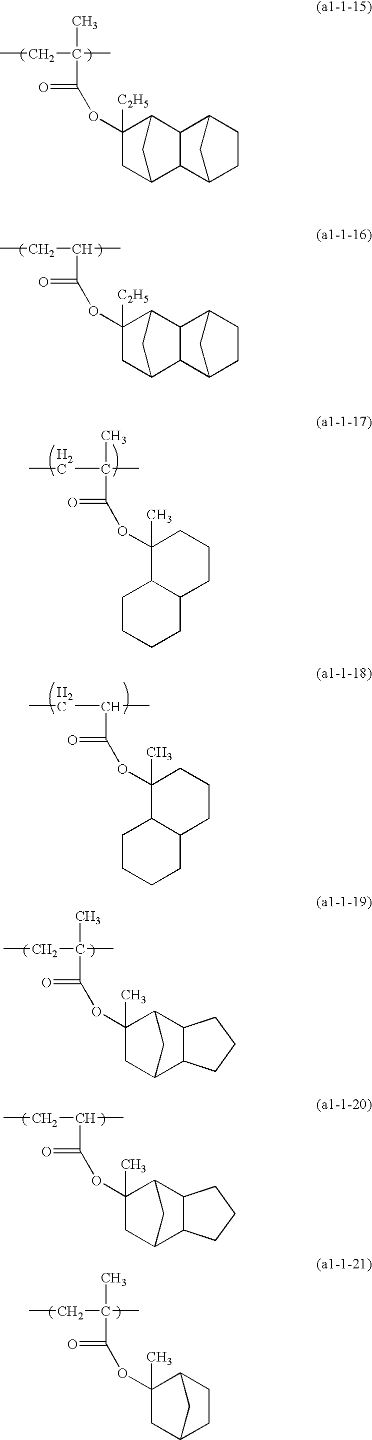

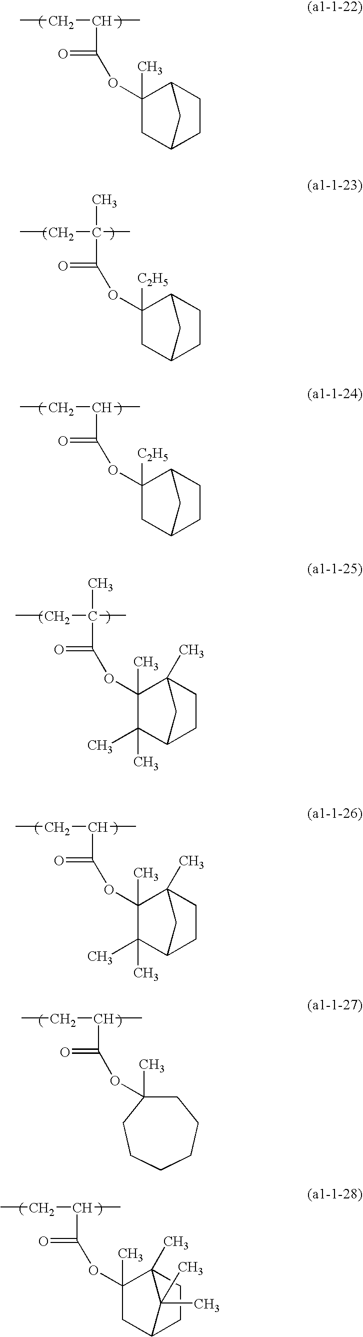

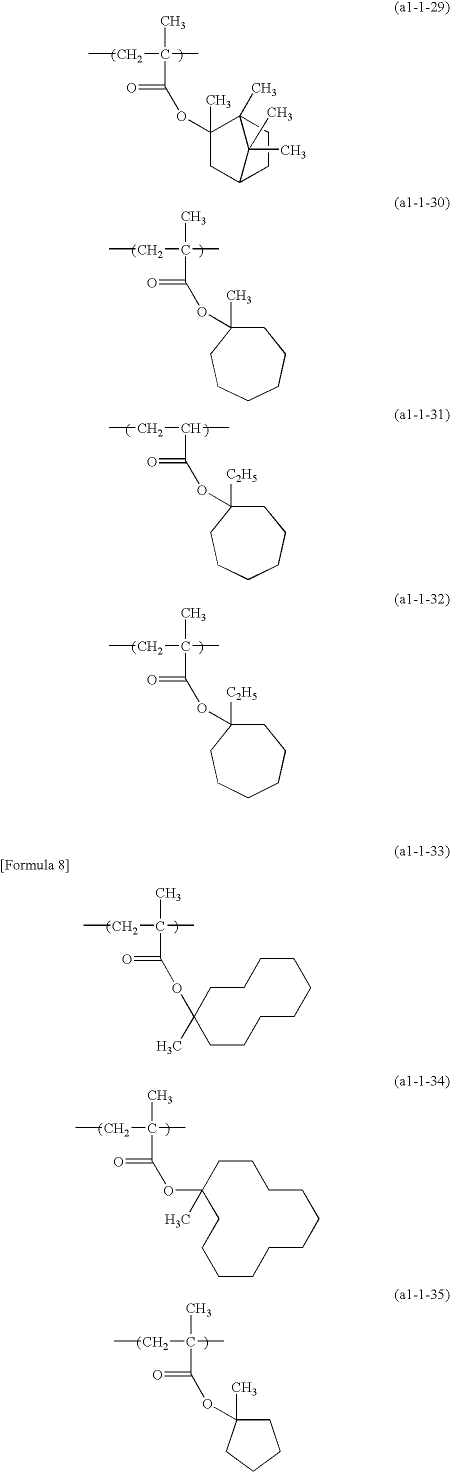

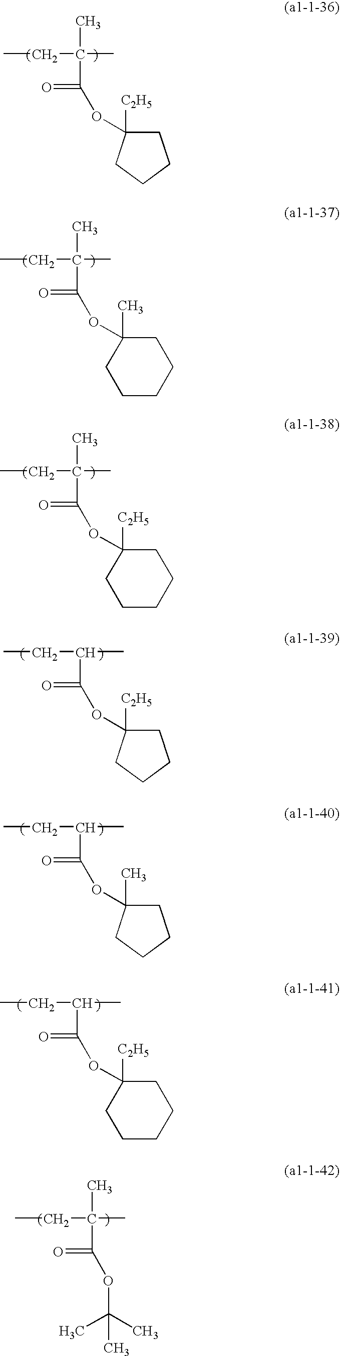

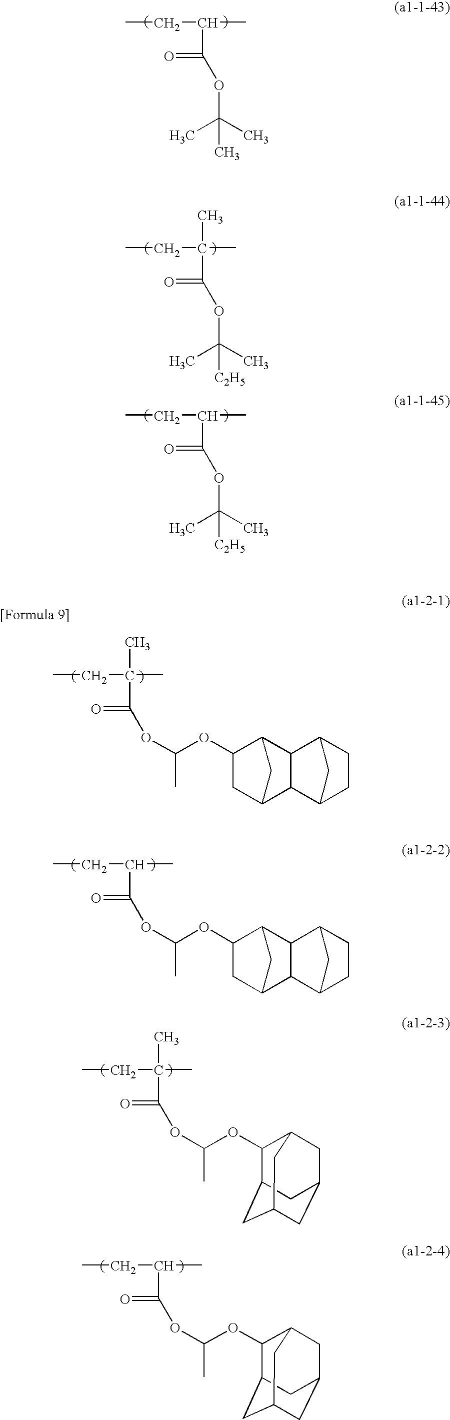

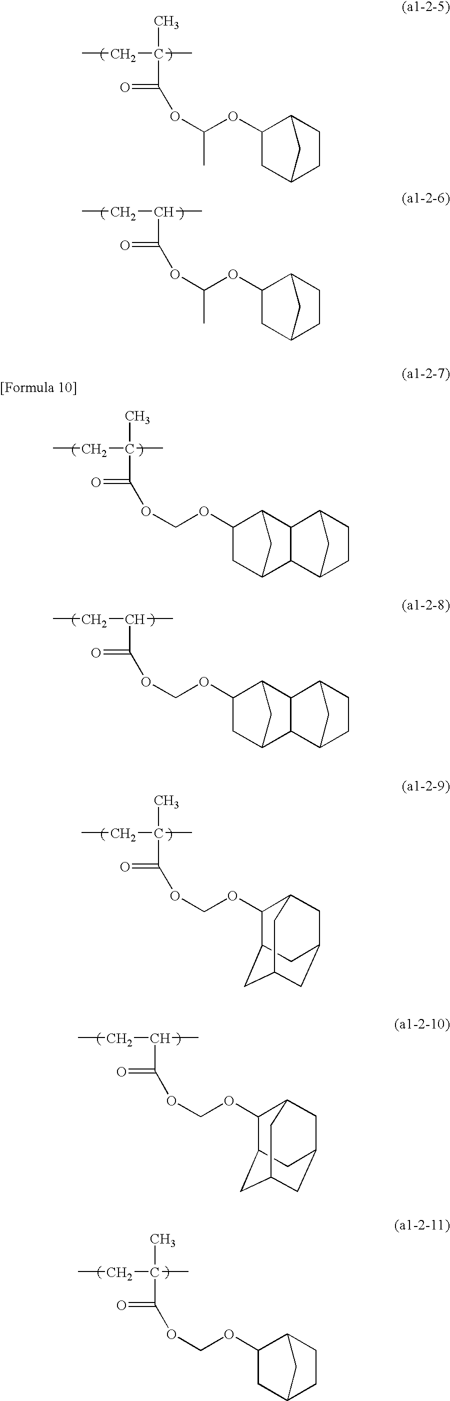

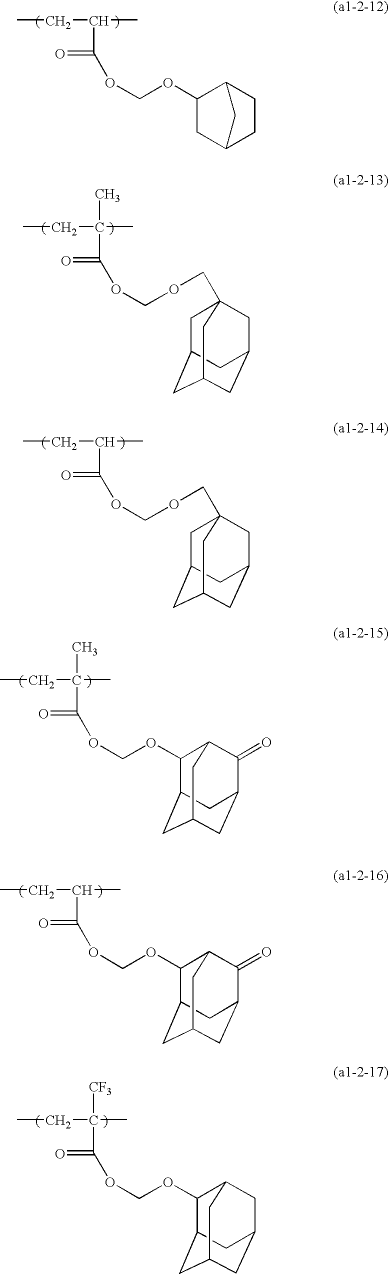

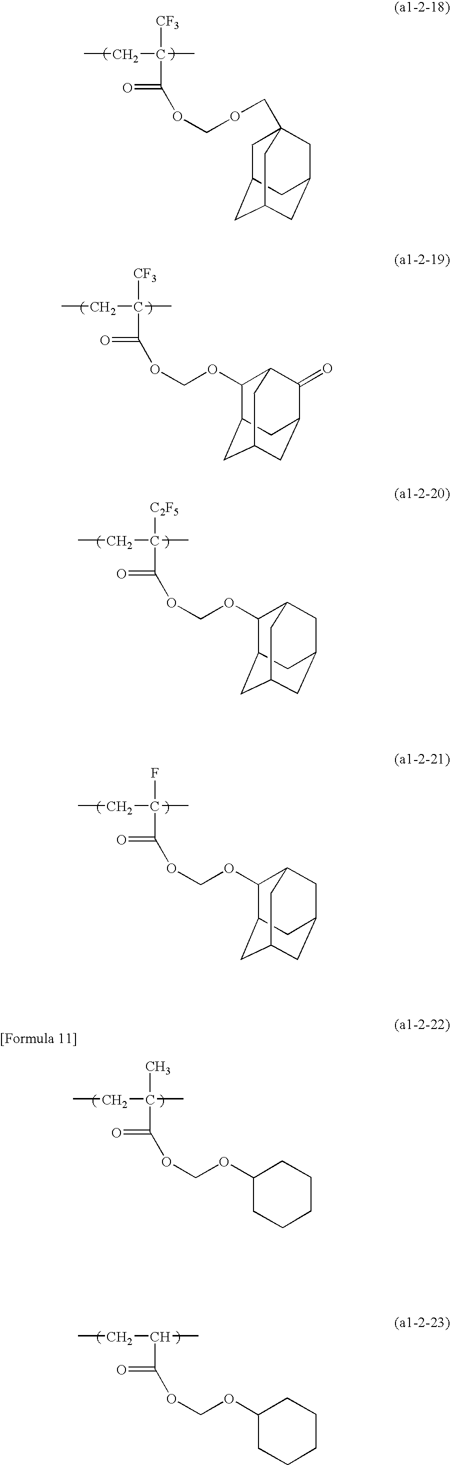

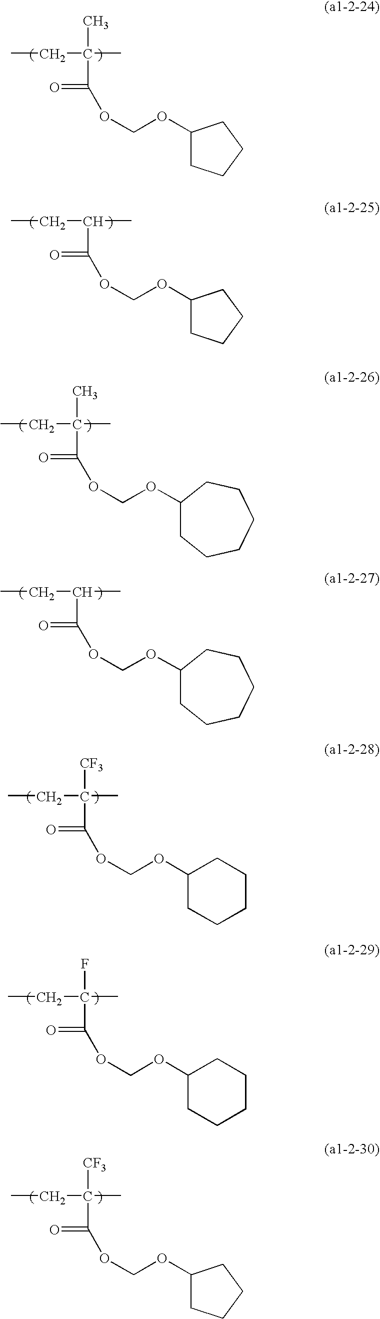

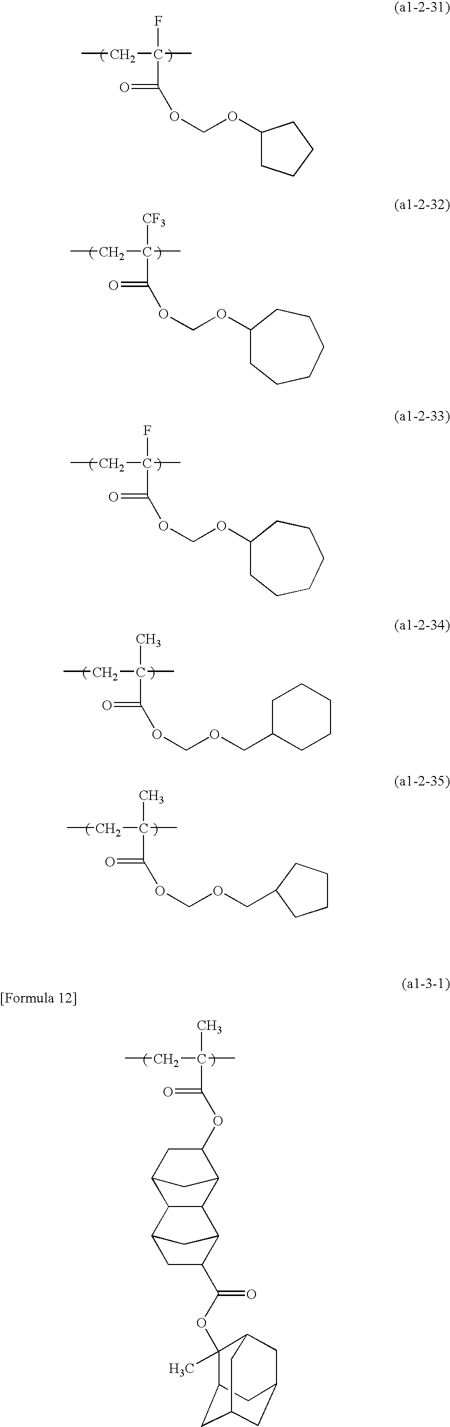

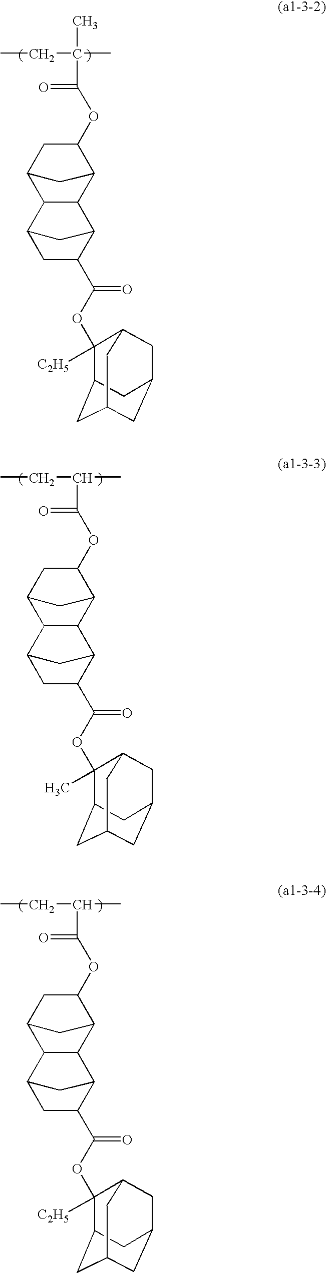

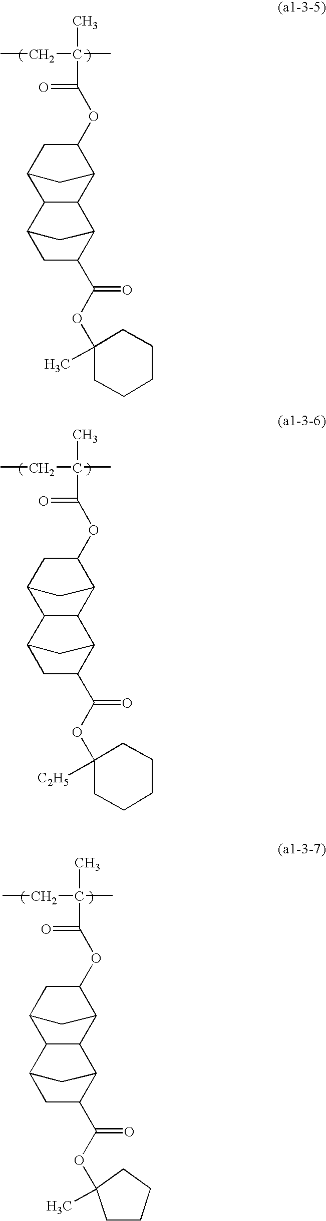

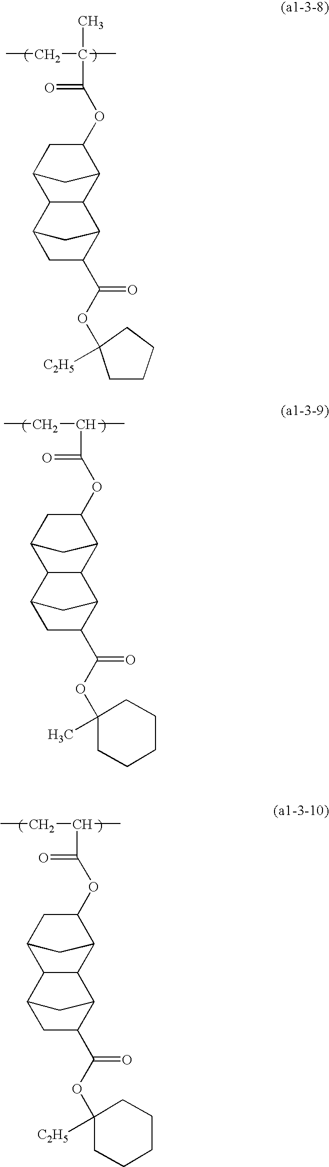

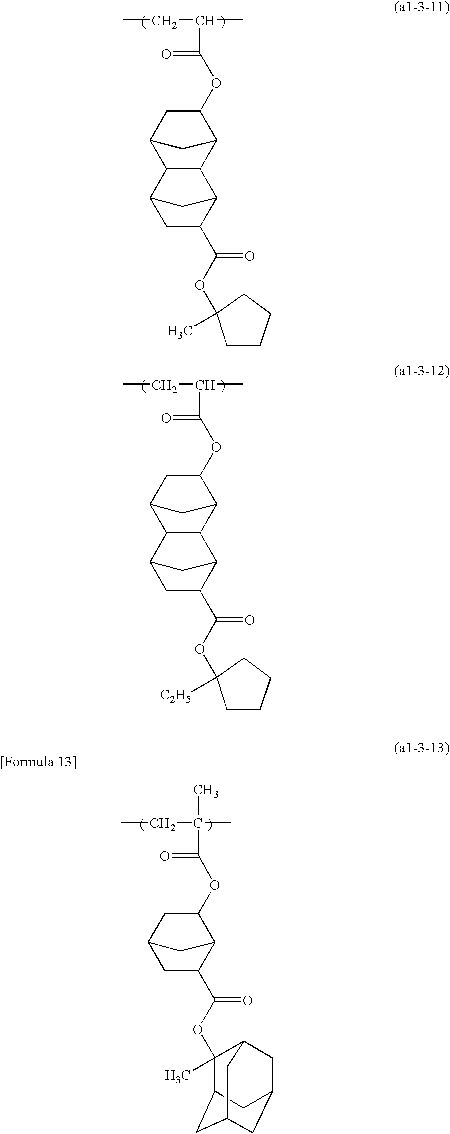

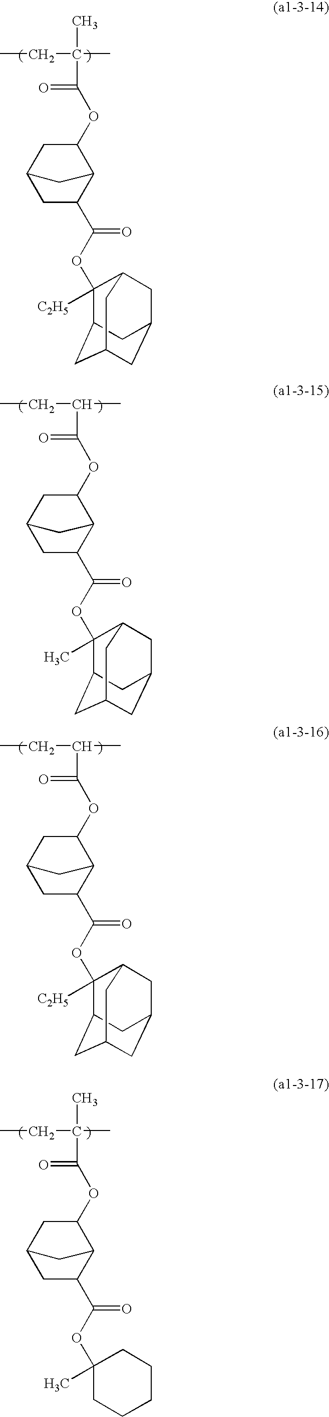

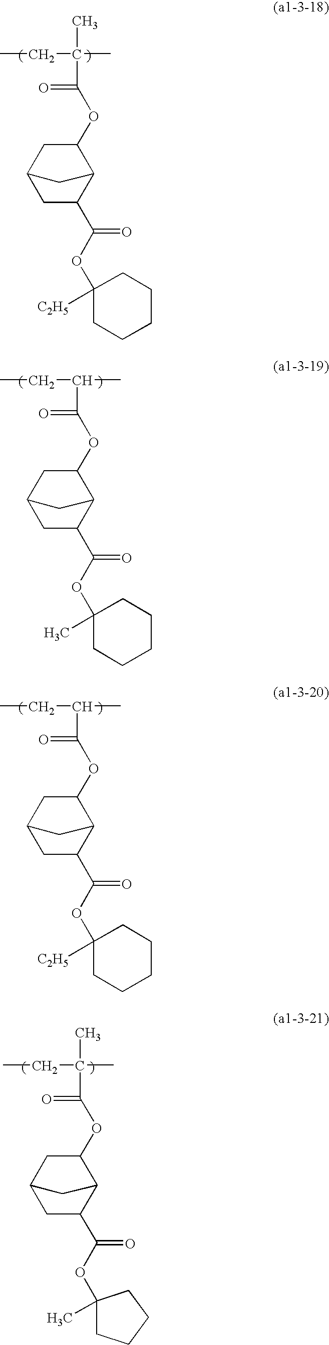

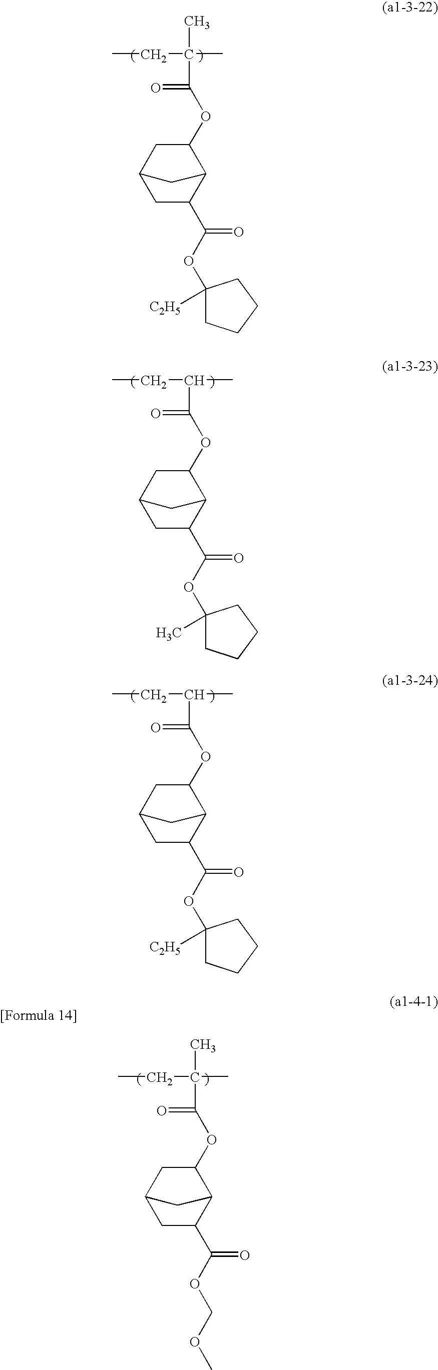

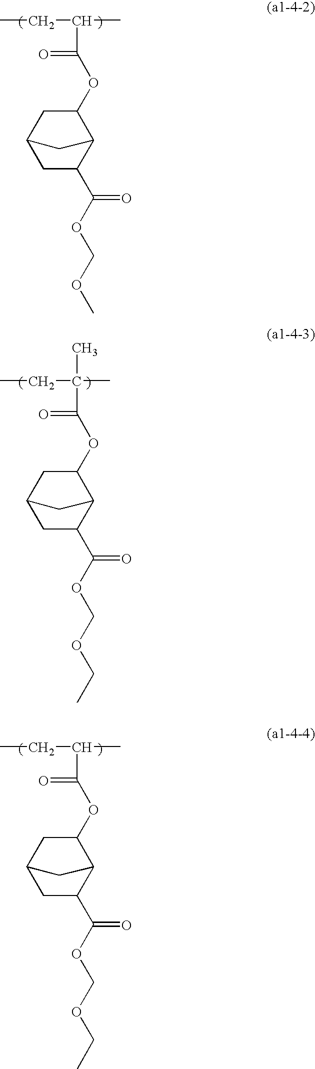

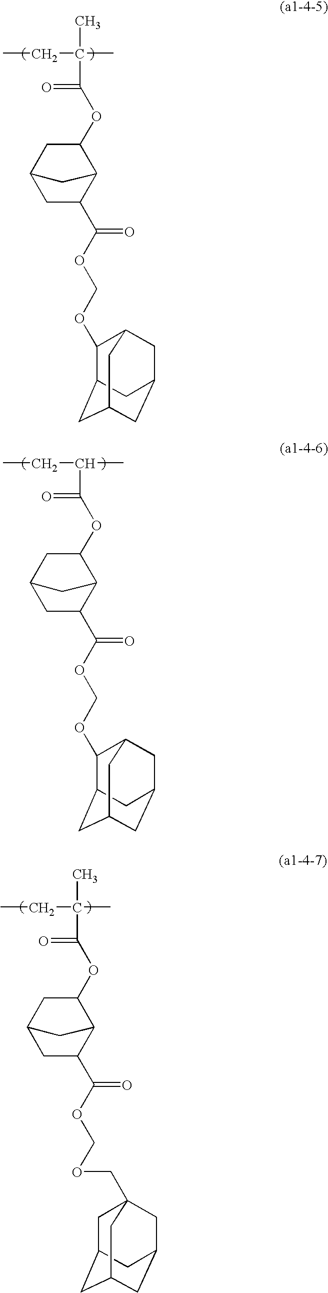

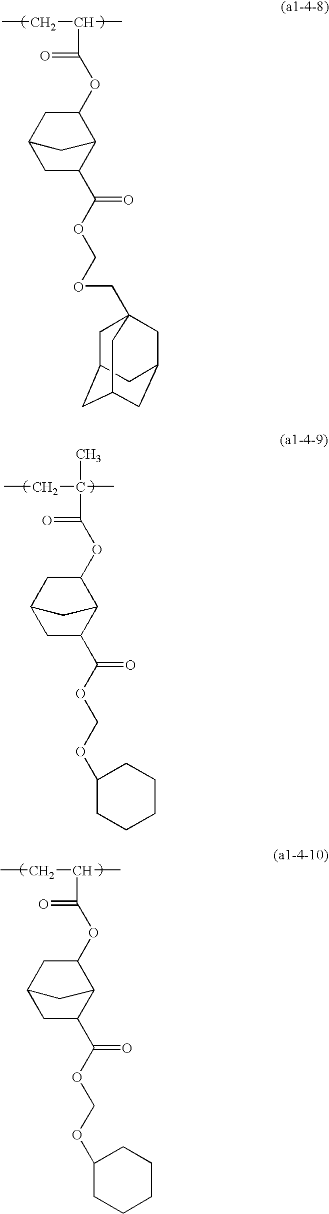

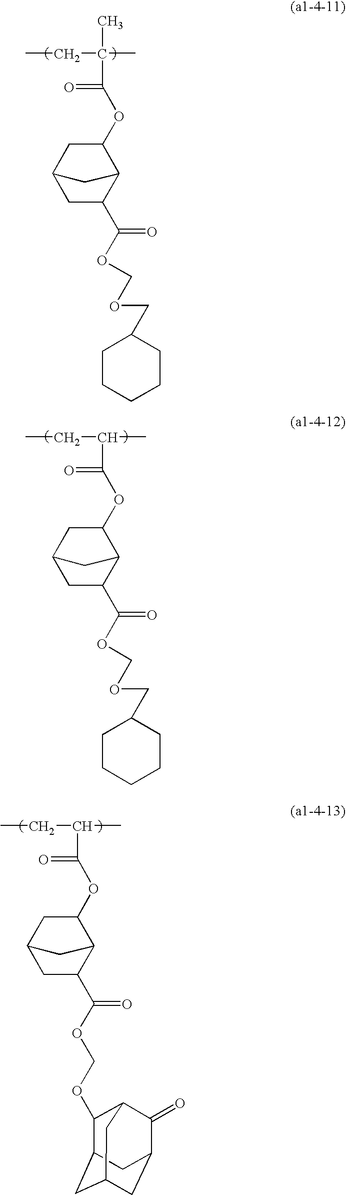

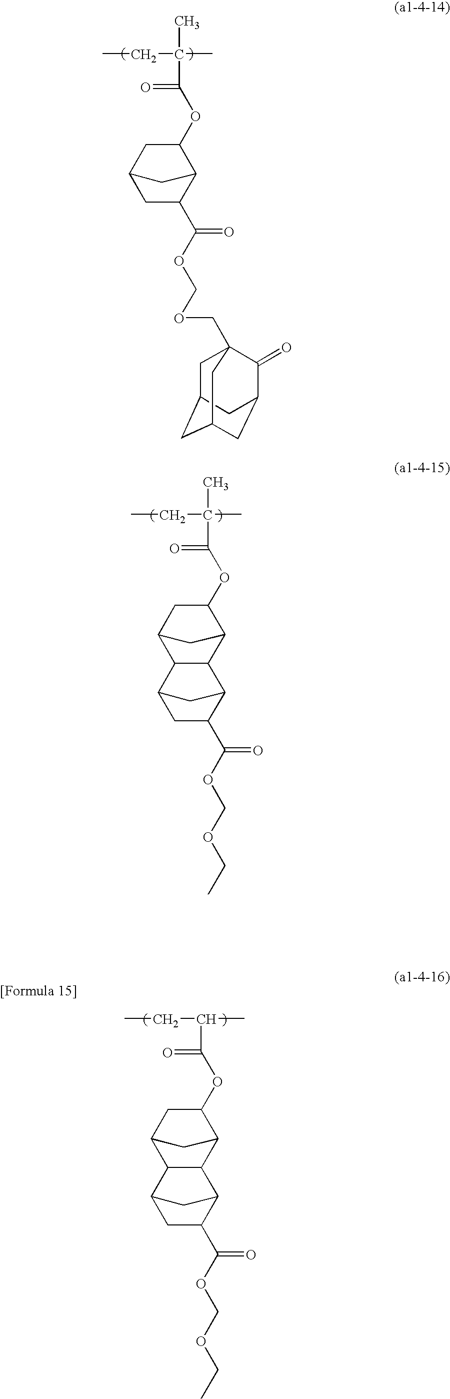

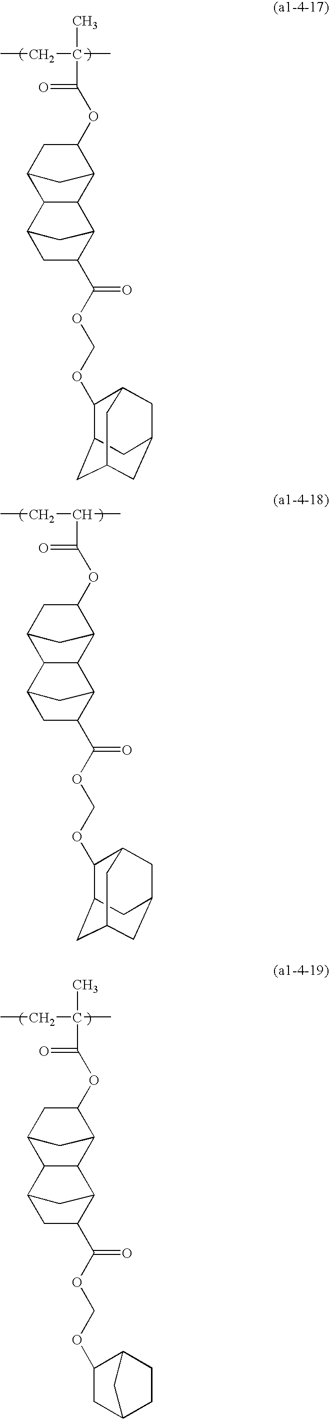

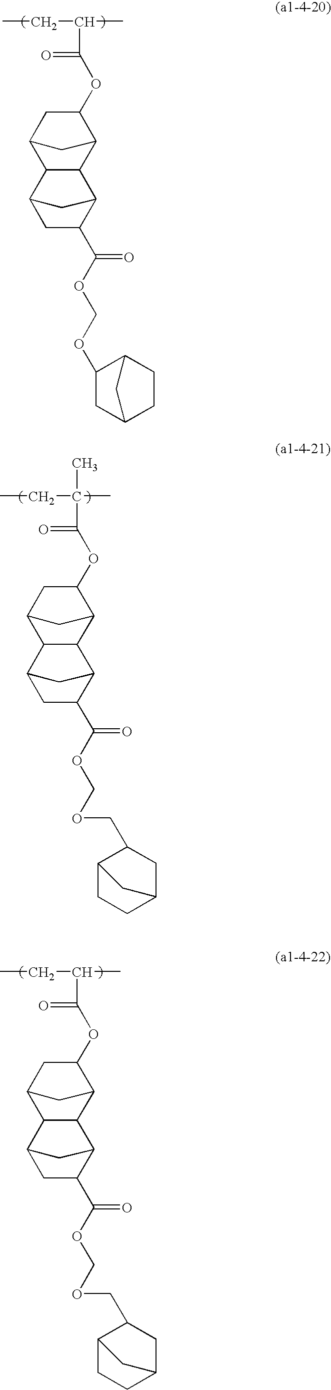

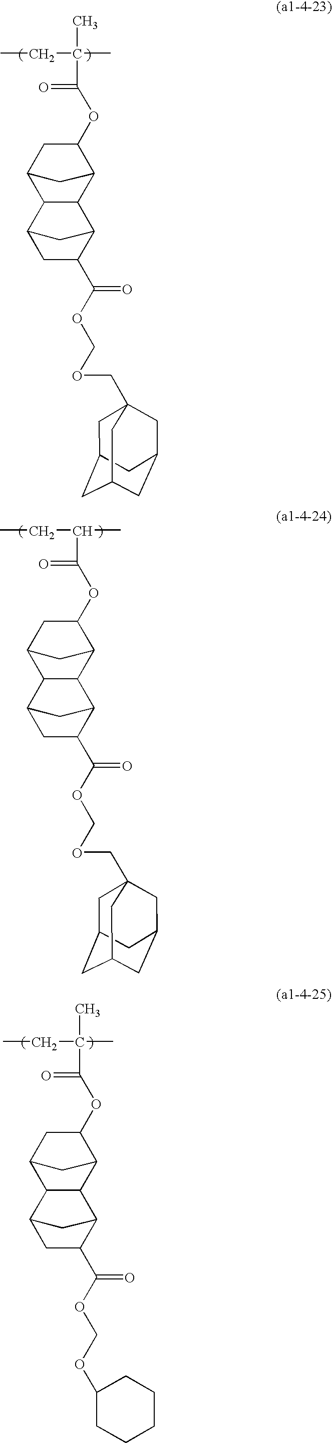

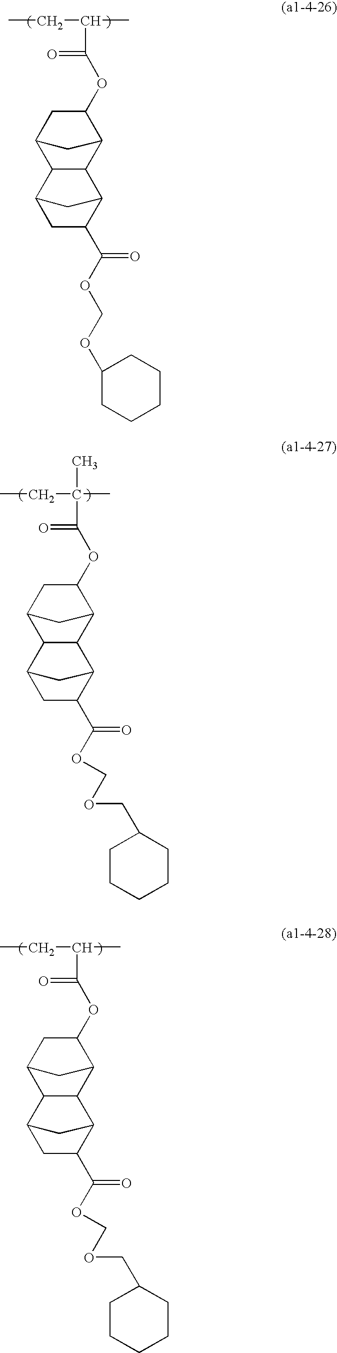

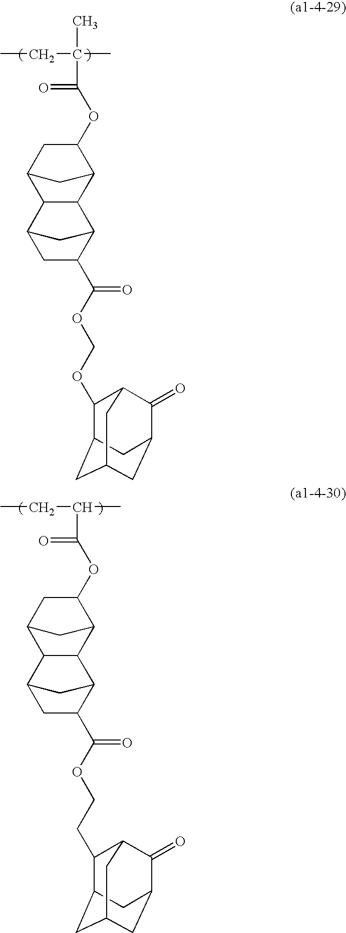

As the structural unit (a1), either a single type of structural unit may be used alone, or a combination of two or more different structural units may be used. Of the various possibilities, structural units represented by the general formula (a1-1) are preferred, and one or more units selected from amongst structural units represented by the formulas (a1-1-1) to (a1-1-6) and the formulas (a1-1-35) to (a1-1-41) are the most desirable.

Moreover, as the structural unit (a1), units represented by a general formula (a1-1-01) shown below, which includes the structural units of the formulas (a1-1-1) through (a1-1-4), and units represented by a general formula (a1-1-02) shown below, which includes the structural units of the formulas (a1-1-35) to (a1-1-41) are particularly desirable.

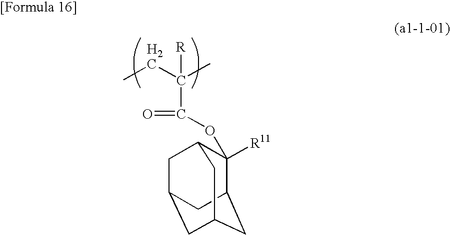

(wherein, R represents a hydrogen atom, halogen atom, lower alkyl group, or halogenated lower alkyl group, and R¹¹ represents a lower alkyl group)

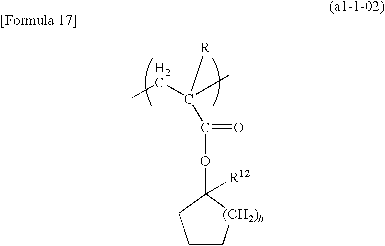

(wherein, R represents a hydrogen atom, halogen atom, lower alkyl group, or halogenated lower alkyl group, R¹² represents a lower alkyl group, and h represents an integer from 1 to 3)

In the general formula (a1-1-01), the halogen atom, lower alkyl group or halogenated lower alkyl group represented by R are as described above for the halogen atom, lower alkyl group or halogenated lower alkyl group that may be bonded to the α-position of an acrylate ester. The lower alkyl group of R¹¹ is the same as the lower alkyl group defined for the group R, is preferably a methyl group or ethyl group, and is most preferably a methyl group.

In the general formula (a1-1-02), the halogen atom, lower alkyl group or halogenated lower alkyl group represented by R are as described above for the halogen atom, lower alkyl group or halogenated lower alkyl group that may be bonded to the α-position of an acrylate ester. The lower alkyl group of R¹² is the same as the lower alkyl group defined for the group R, is preferably a methyl group or ethyl group, and is most preferably an ethyl group. h is preferably either 1 or 2, and is most preferably 2.

The proportion of the structural unit (a1) within the copolymer (A1), relative to the combined total of all the structural units that constitute the copolymer (A1), is preferably within a range from 10 to 80 mol %, even more preferably from 20 to 70 mol %, and is most preferably from 25 to 50 mol %. Ensuring that this proportion is at least as large as the lower limit of the above range enables a pattern to be readily obtained when the copolymer is used in a resist composition, whereas ensuring that the proportion is no greater than the upper limit enables a more favorable balance to be achieved with the other structural units.

Structural Unit (a2)

The copolymer (A1) also includes a structural unit (a2) derived from an acrylate ester that contains a lactone-containing cyclic group.

Here, a lactone-containing cyclic group refers to a cyclic group that contains a ring containing a —O—C(O)— structure (namely, a lactone ring). This lactone ring is counted as the first ring, and groups that contain only the lactone ring are referred to as monocyclic groups, whereas groups that also contain other ring structures are described as polycyclic groups regardless of the structure of the other rings. When the copolymer (A1) is used in the formation of a resist film, the lactone-containing cyclic group of the structural unit (a2) is effective in improving the adhesion of the resist film to the substrate and enhancing the hydrophilicity relative to the developing solution.

As the structural unit (a2), any unit can be used without any particular restrictions.

Specifically, examples of lactone-containing monocyclic groups include groups in which one hydrogen atom has been removed from γ-butyrolactone. Furthermore, examples of lactone-containing polycyclic groups include groups in which one hydrogen atom has been removed from a lactone ring-containing bicycloalkane, tricycloalkane, or tetracycloalkane.

More specific examples of the structural unit (a2) include the structural units represented by general formulas (a2-1) to (a2-5) shown below.

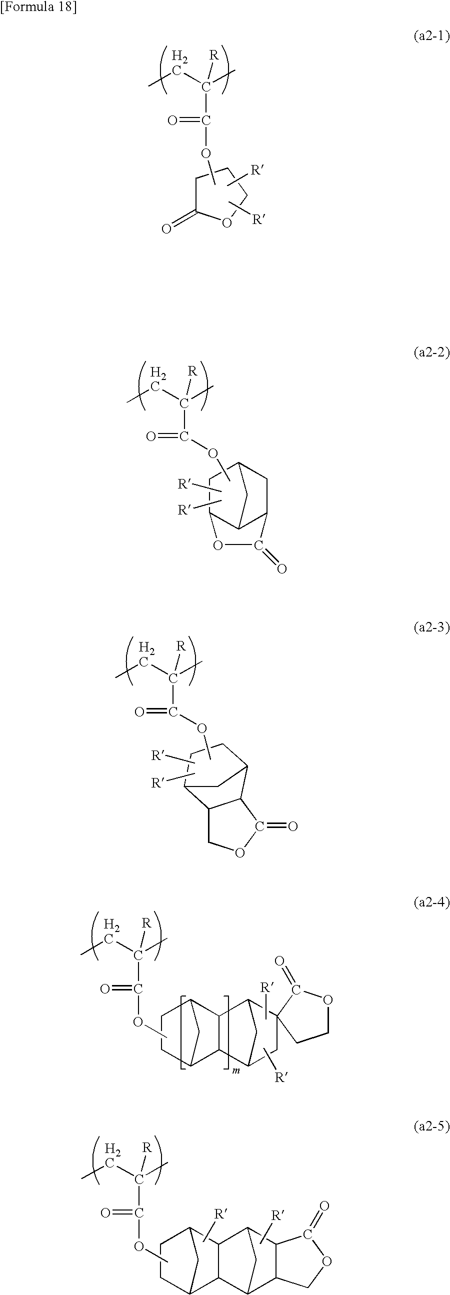

[wherein, R represents a hydrogen atom, halogen atom, lower alkyl group, or halogenated lower alkyl group, R′ represents a hydrogen atom, lower alkyl group, or alkoxy group of 1 to 5 carbon atoms, and m represents an integer of 0 or 1]

The group R within the general formulas (a2-1) to (a2-5) is as defined above for R in the structural unit (a1).

Examples of the lower alkyl group represented by R′ include the same lower alkyl groups as those described above for the group R in the structural unit (a1).

In the general formulas (a2-1) to (a2-5), considering factors such as industrial availability, R′ is preferably a hydrogen atom.

Specific examples of structural units of the above general formulas (a2-1) to (a2-5) are shown below.

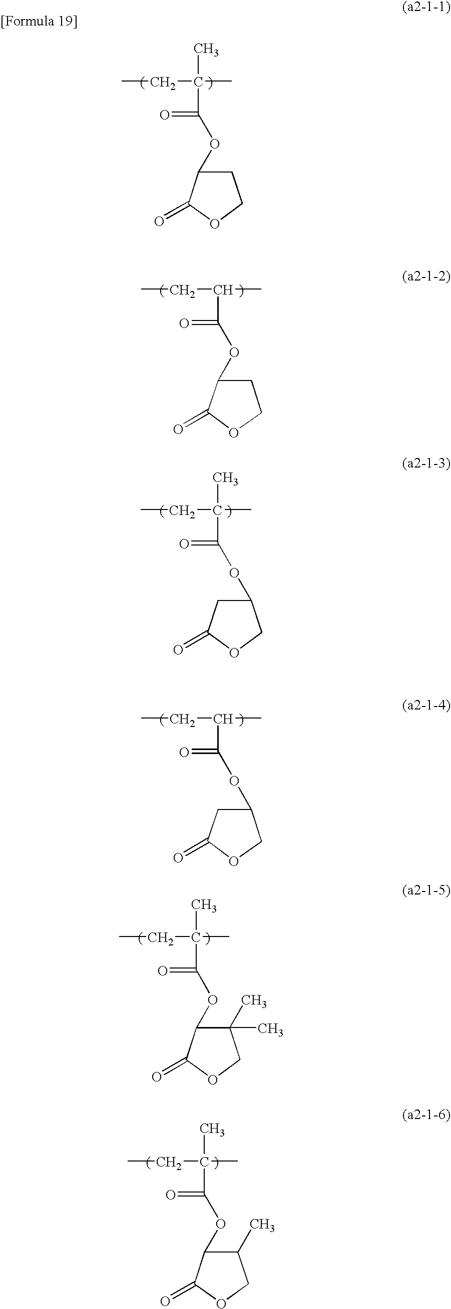

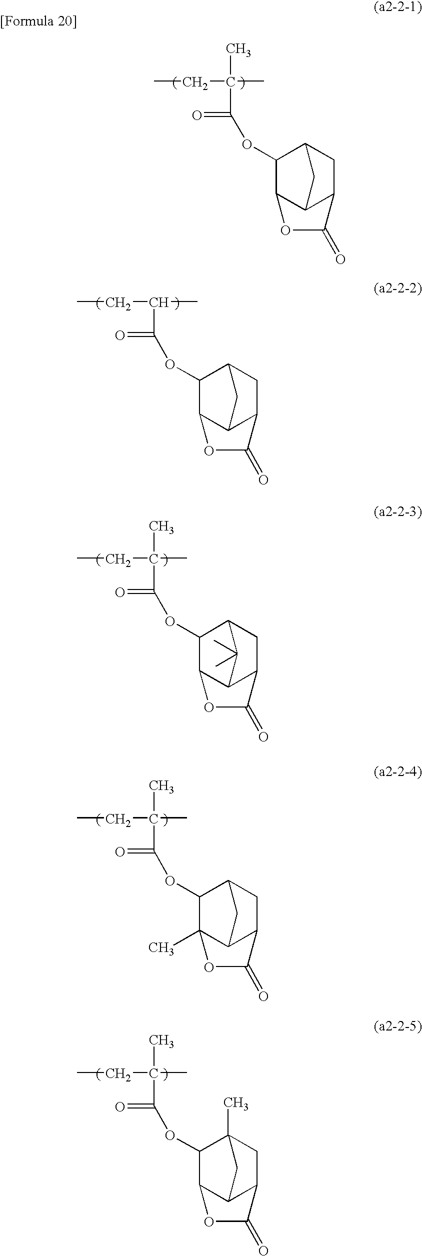

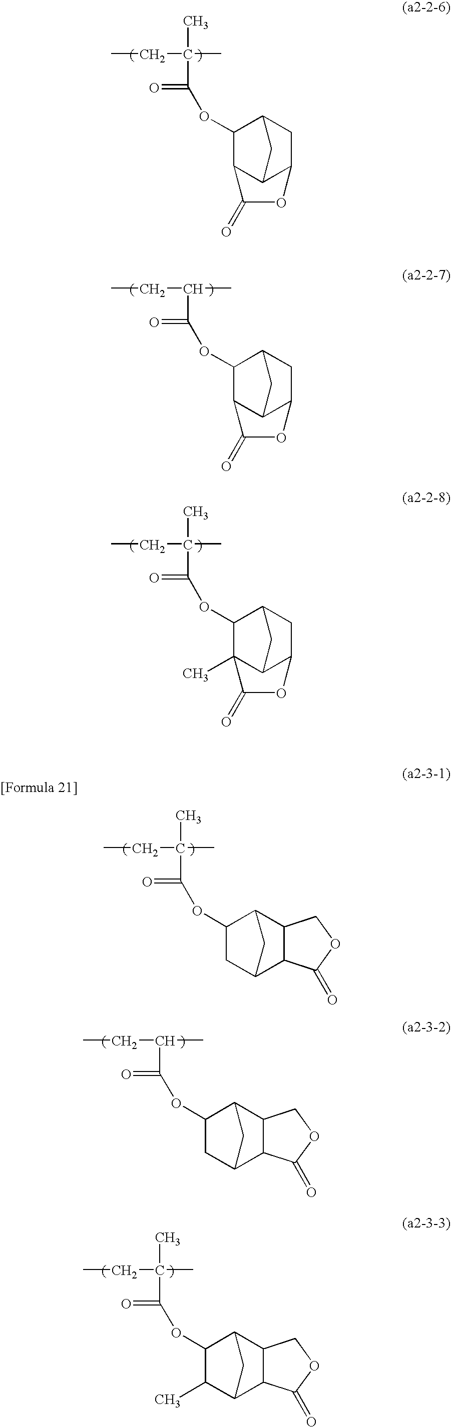

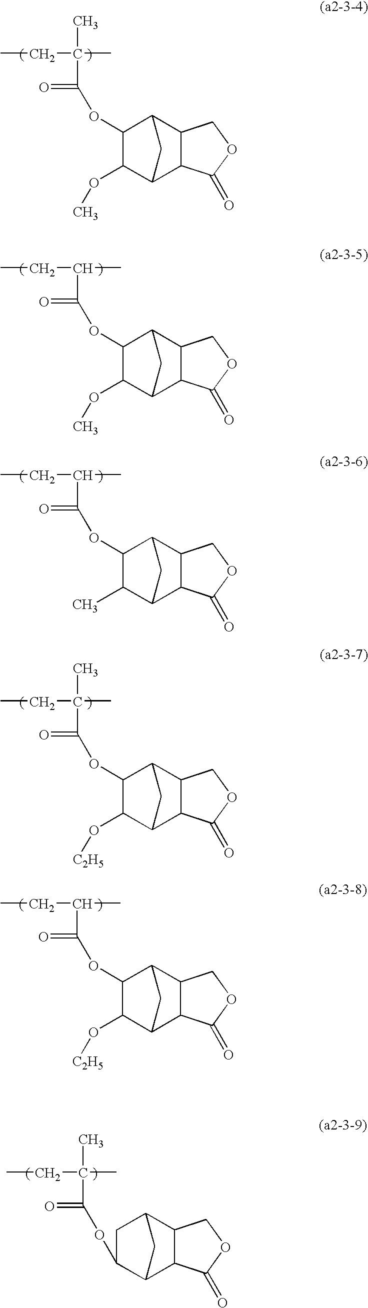

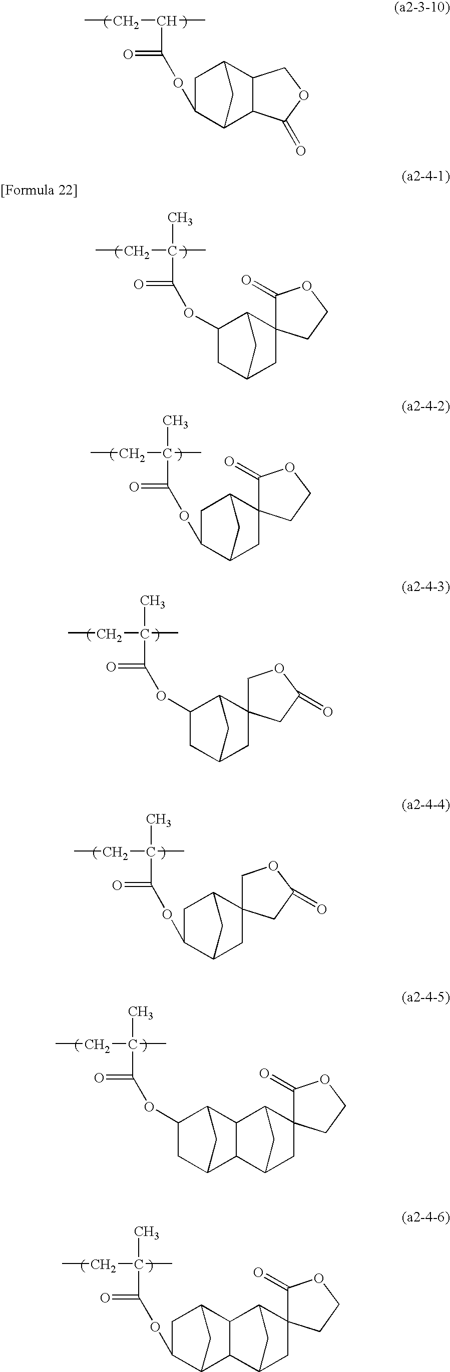

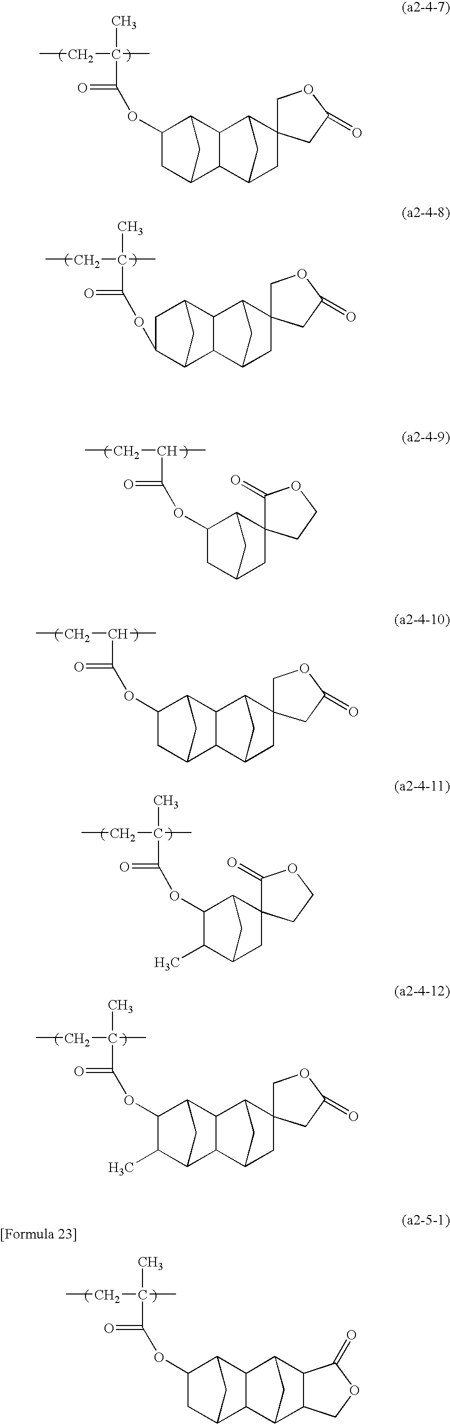

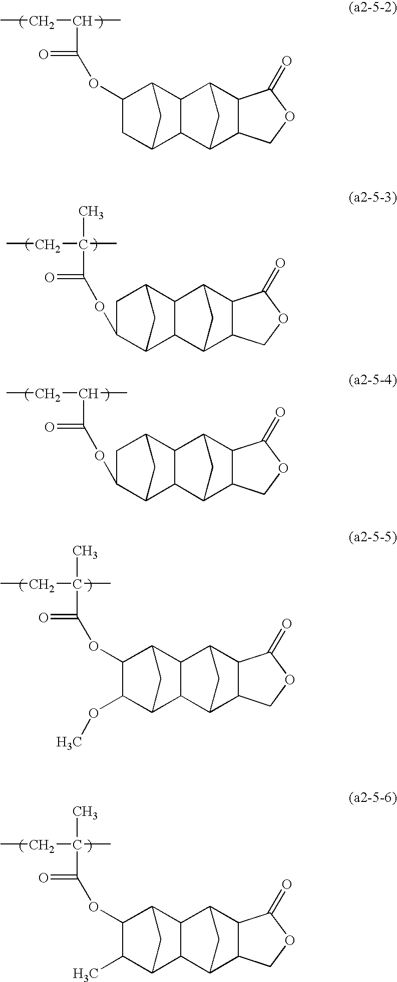

Of the above structural units, the use of at least one structural unit selected from units of the general formulas (a2-1) to (a2-5) is preferred, and the use of at least one structural unit selected from units of the general formulas (a2-1) to (a2-3) is even more desirable. Specifically, the use of at least one structural unit selected from amongst the chemical formulas (a2-1-1), (a2-1-2), (a2-2-1), (a2-2-2), (a2-3-1), (a2-3-2), (a2-3-9), and (a2-3-10) is particularly preferred.

In the copolymer (A1), as the structural unit (a2), either a single type of structural unit may be used alone, or a combination of two or more different structural units may be used.

The proportion of the structural unit (a2) within the copolymer (A1), relative to the combined total of all the structural units that constitute the copolymer (A1), is preferably within a range from 5 to 60 mol %, even more preferably from 10 to 50 mol %, and is most preferably from 20 to 50 mol %. Ensuring that this proportion is at least as large as the lower limit of this range enables the effects obtained by including the structural unit (a2) to be more readily realized, whereas ensuring that the proportion is no greater than the upper limit enables a more favorable balance to be achieved with the other structural units.

Structural Unit (a3)

In addition to the aforementioned structural units (a1) and (a2), the copolymer (A1) also includes a structural unit (a3) derived from an acrylate ester that contains a polar group-containing aliphatic hydrocarbon group.

Including the structural unit (a3) enhances the hydrophilicity of the component (A), thereby improving the affinity with the developing solution, improving the alkali solubility within the exposed portions of the resist, and contributing to an improvement in the resolution.

Examples of the polar group include a hydroxyl group, cyano group, carboxyl group, or hydroxyalkyl group in which a portion of the hydrogen atoms of the alkyl group have been substituted with fluorine atoms or the like, although a hydroxyl group is particularly preferred.

Examples of the aliphatic hydrocarbon group include straight-chain or branched hydrocarbon groups (and preferably alkylene groups) of 1 to 10 carbon atoms, and polycyclic aliphatic hydrocarbon groups (polycyclic groups). These polycyclic groups can be selected appropriately from the multitude of groups that have been proposed for the resins of resist compositions designed for use with ArF excimer lasers.

Of the various possibilities, structural units derived from an acrylate ester that includes an aliphatic polycyclic group containing a hydroxyl group, cyano group, carboxyl group, or a hydroxyalkyl group in which a portion of the hydrogen atoms of the alkyl group have been substituted with fluorine atoms are particularly preferred. Examples of suitable polycyclic groups include groups in which one or more hydrogen atoms have been removed from a bicycloalkane, tricycloalkane or tetracycloalkane or the like. Specific examples include groups in which one or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, groups in which two or more hydrogen atoms have been removed from norbornane, and groups in which two or more hydrogen atoms have been removed from tetracyclododecane are preferred industrially.

When the hydrocarbon group within the polar group-containing aliphatic hydrocarbon group is a straight-chain or branched hydrocarbon group of 1 to 10 carbon atoms, the structural unit (a3) is preferably a structural unit derived from the hydroxyethyl ester of the acrylic acid, whereas when the hydrocarbon group is a polycyclic group, examples of preferred structural units include the structural units represented by a formula (a3-1), the structural units represented by a formula (a3-2), and the structural units represented by a formula (a3-3), all of which are shown below.

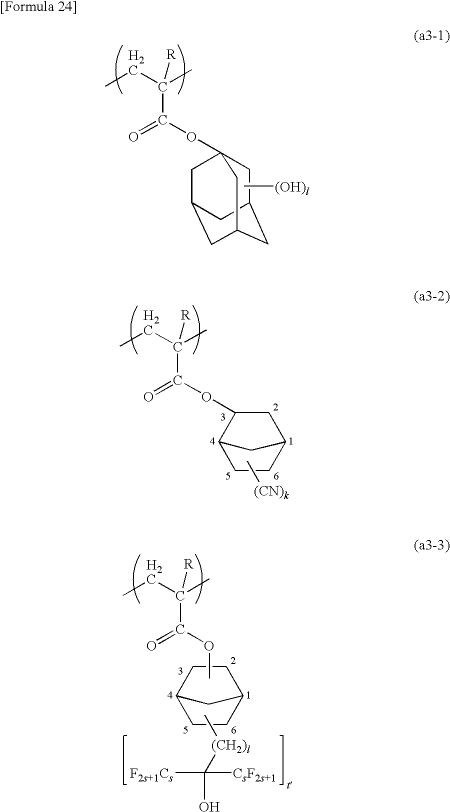

(wherein, R represents a hydrogen atom, halogen atom, lower alkyl group or halogenated lower alkyl group, j represents an integer from 1 to 3, k represents an integer from 1 to 3, t′ represents an integer from 1 to 3, I represents an integer from 1 to 5, and s represents an integer from 1 to 3)

In the general formulas (a3-1) to (a3-3), the halogen atom, lower alkyl group or halogenated lower alkyl group represented by R are as described above for the halogen atom, lower alkyl group or halogenated lower alkyl group that may be bonded to the α-position of an acrylate ester.

In the formula (a3-1), the value of j is preferably either 1 or 2, and is most preferably 1. In those cases where j is 2, the hydroxyl groups are preferably bonded to position 3 and position 5 of the adamantyl group. In those cases where j is 1, the hydroxyl group is preferably bonded to position 3 of the adamantyl group.

The value of j is preferably 1, and units in which the hydroxyl group is bonded to position 3 of the adamantyl group are particularly desirable.

In the formula (a3-2), the value of k is preferably 1. The cyano group is preferably bonded to either position 5 or position 6 of the norbornyl group.

In the formula (a3-3), the value of t′ is preferably 1. The value of 1 is also preferably 1. The value of s is also preferably 1. In these units, a 2-norbornyl group or 3-norbornyl group is preferably bonded to the carboxyl group terminal of the acrylic acid. A fluorinated alkyl alcohol (a hydroxyalkyl group in which a portion of the alkyl group hydrogen atoms have been substituted with fluorine atoms) is preferably bonded to either position 5 or 6 of the norbornyl group.

As the structural unit (a3), either a single type of structural unit may be used alone, or a combination of two or more different structural units may be used.

The proportion of the structural unit (a3) within the copolymer (A1), relative to the combined total of all the structural units that constitute the copolymer (A1), is preferably within a range from 5 to 50 mol %, even more preferably from 5 to 40 mol %, and is most preferably from 5 to 25 mol %.

Structural Unit (a4)

The copolymer (A1) may also include other structural units (a4) besides the structural units (a1) to (a3) described above, provided the inclusion of these other units does not impair the effects of the present invention.

There are no particular restrictions on the structural unit (a4), provided it cannot be classified as one of the above structural units (a1) through (a3), and any of the multitude of conventional structural units used within resist resins for ArF excimer lasers or KrF excimer lasers (and particularly for ArF excimer lasers) can be used.

As the structural unit (a4), a structural unit derived from an acrylate ester that contains a non-acid-dissociable aliphatic polycyclic group is preferred. Examples of the polycyclic group include the same groups as those exemplified above in relation to the structural unit (a1) and the structural unit (a3), and any of the multitude of conventional polycyclic groups used within the resin component of resist compositions for ArF excimer lasers or KrF excimer lasers (and particularly for ArF excimer lasers) can be used.

In particular, at least one group selected from amongst a tricyclodecanyl group, adamantyl group, tetracyclododecanyl group, isobornyl group, and norbornyl group is preferred in terms of factors such as industrial availability. In these polycyclic groups, a hydrogen atom may also be substituted with a straight-chain or branched alkyl group of 1 to 5 carbon atoms.

Specific examples of the structural unit (a4) include units with structures represented by general formulas (a4-1) to (a4-5) shown below.

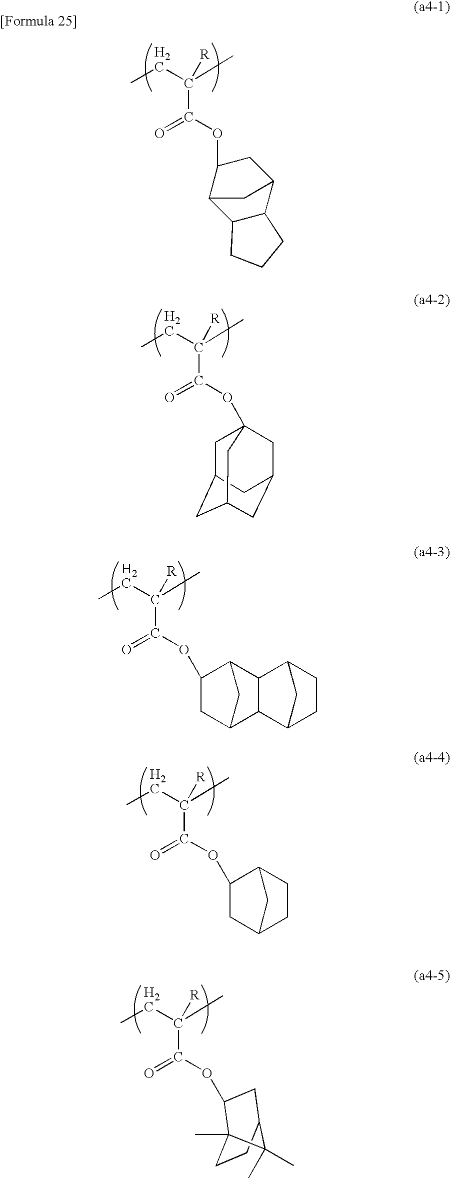

(wherein, R represents a hydrogen atom, halogen atom, lower alkyl group, or halogenated lower alkyl group)

In the general formulas (a4-1) to (a4-5), the halogen atom, lower alkyl group or halogenated lower alkyl group represented by R are as described above for the halogen atom, lower alkyl group or halogenated lower alkyl group that may be bonded to the α-position of an acrylate ester.

In those cases where the structural unit (a4) is included within the copolymer (A1), the proportion of the structural unit (a4), relative to the combined total of all the structural units that constitute the copolymer (A1), is typically within a range from 1 to 30 mol %, and is preferably from 10 to 20 mol %.

In the present invention, the copolymer (A1) is a copolymer that includes the structural unit (a1), the structural unit (a2) and the structural unit (a3), and examples of this copolymer include copolymers formed solely from the structural units (a1), (a2) and (a3), and copolymers formed from the structural units (a1), (a2), (a3) and (a4).

In the component (A), either a single copolymer (A1) may be used alone, or a combination of two or more copolymers may be used.

In the present invention, a copolymer (A1) containing a combination of structural units such as that shown below in the formula (A1-11) is particularly desirable.

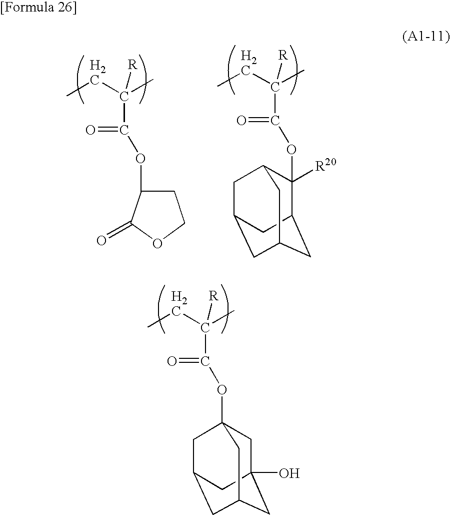

[wherein, R represents a hydrogen atom, halogen atom, lower alkyl group, or halogenated lower alkyl group, and R²⁰ represents a lower alkyl group]

In the formula (A1-11), the halogen atom, lower alkyl group or halogenated lower alkyl group represented by R are as described above for the halogen atom, lower alkyl group or halogenated lower alkyl group that may be bonded to the α-position of an acrylate ester.

In the formula (A1-11), the lower alkyl group of R²⁰ is the same as the lower alkyl group defined for R, is preferably a methyl group or ethyl group, and is most preferably a methyl group.

The copolymer (A1) can be obtained, for example, by conducting a polymerization, via a conventional radical polymerization or the like, of the monomers that yield each of the structural units, using a radical polymerization initiator such as azobisisobutyronitrile (AIBN).

Furthermore, —C(CF₃)₂—OH groups may be introduced at the terminals of the copolymer (A1) by also using a chain transfer agent such as HS—CH₂—CH₂—CH₂—C(CF₃)₂—OH during the above polymerization. A copolymer wherein hydroxyalkyl groups, in which a portion of the hydrogen atoms of the alkyl group have been substituted with fluorine atoms, have been introduced in this manner is effective in reducing the levels of developing defects and LER (line edge roughness: non-uniform irregularities within the line side walls).

Although there are no particular restrictions on the weight average molecular weight (Mw) (the polystyrene equivalent value determined by gel permeation chromatography) of the copolymer (A1), the molecular weight value is preferably within a range from 2,000 to 50,000, even more preferably from 3,000 to 30,000, and is most preferably from 5,000 to 20,000. Provided the molecular weight is smaller than the upper limit of the above range, the copolymer is sufficiently soluble in a resist solvent to enable its use as a resist, whereas provided the molecular weight is greater than the lower limit, the dry etching resistance and cross-sectional shape of the resist pattern are favorable.

Furthermore, the degree of dispersion (Mw/Mn) is preferably within a range from 1.0 to 5.0, even more preferably from 1.0 to 3.0, and is most preferably from 1.2 to 2.5. Mn represents the number average molecular weight.

### <Component (B)>

There are no particular restrictions on the component (B), and any of the known acid generators used within conventional chemically amplified resists can be used. Examples of these acid generators are numerous, and include onium salt-based acid generators such as iodonium salts and sulfonium salts, oxime sulfonate-based acid generators, diazomethane-based acid generators such as bisalkyl or bisaryl sulfonyl diazomethanes and poly(bis-sulfonyl)diazomethanes, nitrobenzyl sulfonate-based acid generators, iminosulfonate-based acid generators, and disulfone-based acid generators.

Examples of suitable onium salt-based acid generators include, for example, the acid generators represented by a general formula (b-0) shown below.

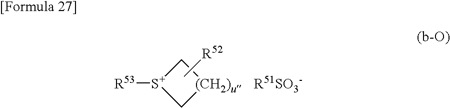

[wherein, R⁵¹ represents a straight-chain, branched-chain or cyclic alkyl group, or a straight-chain, branched-chain or cyclic fluoroalkyl group; R⁵² represents a hydrogen atom, a hydroxyl group, a halogen atom, a straight-chain, branched-chain or cyclic alkyl group, a straight-chain or branched-chain haloalkyl group, or a straight-chain or branched-chain alkoxy group; R⁵³ represents an aryl group that may contain a substituent group; and u″ represents an integer from 1 to 3]

In the general formula (b-0), R⁵¹ represents a straight-chain, branched-chain or cyclic alkyl group, or a straight-chain, branched-chain or cyclic fluoroalkyl group.

The straight-chain or branched-chain alkyl group preferably contains from 1 to 10 carbon atoms, even more from preferably 1 to 8 carbon atoms, and most preferably from 1 to 4 carbon atoms.

The cyclic alkyl group preferably contains from 4 to 12 carbon atoms, even more preferably from 5 to 10 carbon atoms, and most preferably from 6 to 10 carbon atoms.

The fluoroalkyl group preferably contains from 1 to 10 carbon atoms, even more preferably from 1 to 8 carbon atoms, and most preferably from 1 to 4 carbon atoms. Furthermore, the fluorination ratio for the fluoroalkyl group (the ratio of the number of substituted fluorine atoms relative to the total number of hydrogen atoms within the original alkyl group) is preferably within a range from 10 to 100%, and even more preferably from 50 to 100%, and groups in which all of the hydrogen atoms have been substituted with fluorine atoms yield the strongest acids, and are consequently the most desirable.

As the group R⁵¹, a straight-chain alkyl group or fluoroalkyl group is the most desirable.

R⁵² represents a hydrogen atom, a hydroxyl group, a halogen atom, a straight-chain, branched-chain or cyclic alkyl group, a straight-chain or branched-chain haloalkyl group, or a straight-chain or branched-chain alkoxy group.

Examples of the halogen atom represented by R⁵² include a fluorine atom, bromine atom, chlorine atom or iodine atom, and a fluorine atom is preferred.

Examples of the straight-chain or branched-chain alkyl group represented by R⁵² include groups in which the number of carbon atoms is preferably within a range from 1 to 5, even more preferably from 1 to 4, and most preferably from 1 to 3.

Examples of the cyclic alkyl group represented by R⁵² include groups in which the number of carbon atoms is preferably within a range from 4 to 12, even more preferably from 4 to 10, and most preferably from 5 to 10.

Examples of haloalkyl groups represented by R⁵² include groups in which either a portion of, or all of, the hydrogen atoms within the alkyl group have been substituted with halogen atoms. Here, an alkyl group refers to the same type of group as the “straight-chain or branched-chain alkyl group” described above for the group R⁵². Examples of the substituent halogen atom include the same halogen atoms as those described above in relation to “halogen atoms”. In the haloalkyl group, 50 to 100% of the total number of hydrogen atoms are preferably substituted with halogen atoms, and groups in which all of the hydrogen atoms have been substituted are particularly desirable.

Examples of the alkoxy group represented by R⁵² include straight-chain and branched-chain groups in which the number of carbon atoms is preferably within a range from 1 to 5, even more preferably from 1 to 4, and most preferably from 1 to 3.

Of the groups described above, R⁵² is most preferably a hydrogen atom.

R⁵³ represents an aryl group that may contain a substituent group, and examples of the basic ring structure excluding any substituent groups (the matrix structure) include a naphthyl group, phenyl group or anthracenyl group, and from the viewpoints of maximizing the effects of the present invention and ensuring favorable absorption of the exposure light such as the ArF excimer laser light, a phenyl group is preferred.

Examples of the substituent group include a hydroxyl group or a lower alkyl group (which may be a straight-chain or branched-chain group, preferably contains from 1 to 5 carbon atoms, and is most preferably methyl group).

The aryl group represented by R⁵³ preferably contains no substituent groups.

u″ represents an integer from 1 to 3, is preferably either 2 or 3, and is most preferably 3.

Examples of preferred acid generators represented by the general formula (b-0) include the compounds shown below.

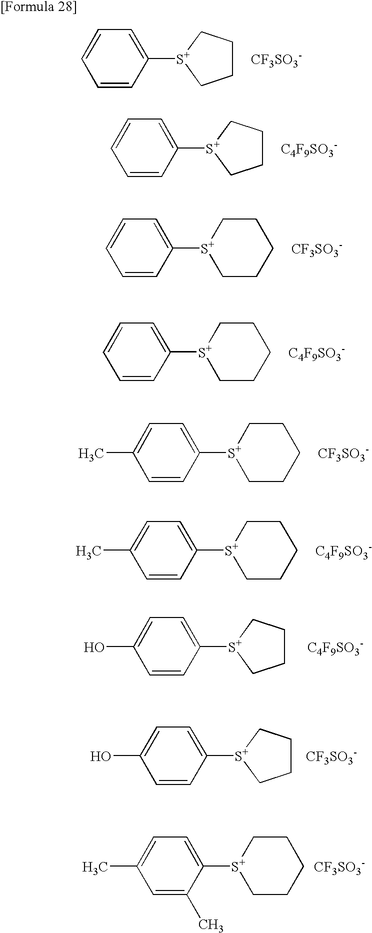

The acid generator represented by the general formula (b-0) may use either a single compound, or a mixture of two or more different compounds.

Furthermore, examples of preferred onium salt-based acid generators other than those represented by the above general formula (b-0) include compounds represented by general formulas (b-1) and (b-2) shown below.

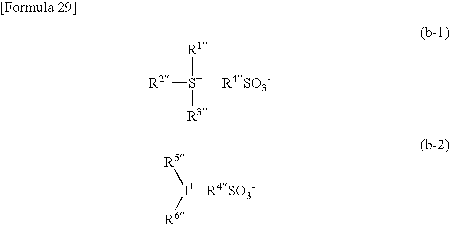

[wherein, R^{1″} to R^{3″}, and R^{5″} to R^{6″} each represent, independently, an aryl group or an alkyl group; and R^{4″} represents a straight-chain, branched or cyclic alkyl group or fluoroalkyl group; provided that at least one of R^{1″} to R^{3″} represents an aryl group, and at least one of R^{5″} to R^{6″} represents an aryl group]

In the formula (b-1), R^{1″} to R^{3″} each represent, independently, an aryl group or an alkyl group. Of the groups R^{1″} to R^{3″}, at least one group represents an aryl group. Compounds in which at least two of R^{1″} to R^{3″} represent aryl groups are preferred, and compounds in which all of R^{1″} to R^{3″} are aryl groups are the most preferred.

There are no particular restrictions on the aryl groups of R^{1″} to R^{3″}, and suitable examples include aryl groups of 6 to 20 carbon atoms, in which either a portion of, or all of, the hydrogen atoms of these aryl groups may be either substituted, or not substituted, with alkyl groups, alkoxy groups, or halogen atoms and the like. In terms of enabling low-cost synthesis, aryl groups of 6 to 10 carbon atoms are preferred. Specific examples of suitable groups include a phenyl group and a naphthyl group.

Alkyl groups that may be used for substitution of the hydrogen atoms of the above aryl groups are preferably alkyl groups of 1 to 5 carbon atoms, and a methyl group, ethyl group, propyl group, n-butyl group or tert-butyl group is the most desirable.

Alkoxy groups that may be used for substitution of the hydrogen atoms of the above aryl groups are preferably alkoxy groups of 1 to 5 carbon atoms, and a methoxy group or ethoxy group is the most desirable. Halogen atoms that may be used for substitution of the hydrogen atoms of the above aryl groups are preferably fluorine atoms.

There are no particular restrictions on the alkyl groups of R^{1″} to R^{3″}, and suitable examples include straight-chain, branched, or cyclic alkyl groups of 1 to 10 carbon atoms. From the viewpoint of achieving excellent resolution, alkyl groups of 1 to 5 carbon atoms are preferred. Specific examples include a methyl group, ethyl group, n-propyl group, isopropyl group, n-butyl group, isobutyl group, n-pentyl group, cyclopentyl group, hexyl group, cyclohexyl group, nonyl group, and decanyl group. Of these, in terms of achieving superior resolution and enabling low-cost synthesis, a methyl group is the most desirable.

Of the above possibilities, compounds in which R^{1″} to R^{3″} each represent a phenyl group or a naphthyl group are the most preferred.

The group R^{4″} represents a straight-chain, branched or cyclic alkyl group or fluoroalkyl group. The straight-chain or branched alkyl group preferably contains from 1 to 10 carbon atoms, even more preferably from 1 to 8 carbon atoms, and most preferably from 1 to 4 carbon atoms.

Suitable cyclic alkyl groups include the same groups as those listed above in relation to the group R^{1″}, and cyclic groups of 4 to 15 carbon atoms are preferred, groups of 4 to 10 carbon atoms are even more preferred, and groups of 6 to 10 carbon atoms are the most desirable.

As the above fluoroalkyl group, groups of 1 to 10 carbon atoms are preferred, groups of 1 to 8 carbon atoms are even more preferred, and groups of 1 to 4 carbon atoms are the most desirable. Furthermore, the fluorination ratio of the fluoroalkyl group (namely, the fluorine atom proportion within the alkyl group) is preferably within a range from 10 to 100%, and even more preferably from 50 to 100%, and groups in which all of the hydrogen atoms have been substituted with fluorine atoms yield the strongest acids, and are consequently the most desirable.

The group R^{4″} is most preferably a straight-chain or cyclic alkyl group, or a fluoroalkyl group.

In the formula (b-2), R^{5″} to R^{6″} each represent, independently, an aryl group or an alkyl group. At least one of R^{5″} to R^{6″} represents an aryl group. Compounds in which all of R^{5″} to R^{6″} are aryl groups are the most preferred.

Suitable examples of the aryl groups of the groups R^{5″} to R^{6″} include the same aryl groups as those described above for the groups R^{1″} to R^{3″}.

Suitable examples of the alkyl groups of the groups R^{5″} to R^{6″} include the same alkyl groups as those described above for the groups R^{1″} to R^{3″}.

Of the above possibilities, compounds in which R^{5″} to R^{6″} are all phenyl groups are the most preferred.

Suitable examples of the group R^{4″} in the formula (b-2) include the same groups as those described for the group R^{4″} in the aforementioned formula (b-1).

Specific examples of suitable onium salt-based acid generators represented by the formula (b-1) or (b-2) include diphenyliodonium trifluoromethanesulfonate or nonafluorobutanesulfonate, bis(4-tert-butylphenyl)iodonium trifluoromethanesulfonate or nonafluorobutanesulfonate, triphenylsulfonium trifluoromethanesulfonate, heptafluoropropanesulfonate or nonafluorobutanesulfonate, tri(4-methylphenyl)sulfonium trifluoromethanesulfonate, heptafluoropropanesulfonate or nonafluorobutanesulfonate, dimethyl(4-hydroxynaphthyl)sulfonium trifluoromethanesulfonate, heptafluoropropanesulfonate or nonafluorobutanesulfonate, monophenyldimethylsulfonium trifluoromethanesulfonate, heptafluoropropanesulfonate or nonafluorobutanesulfonate, diphenylmonomethylsulfonium trifluoromethanesulfonate, heptafluoropropanesulfonate or nonafluorobutanesulfonate, (4-methylphenyl)diphenylsulfonium trifluoromethanesulfonate, heptafluoropropanesulfonate or nonafluorobutanesulfonate, (4-methoxyphenyl)diphenylsulfonium trifluoromethanesulfonate, heptafluoropropanesulfonate or nonafluorobutanesulfonate, tri(4-tert-butyl)phenylsulfonium trifluoromethanesulfonate, heptafluoropropanesulfonate or nonafluorobutanesulfonate, diphenyl(1-(4-methoxy)naphthyl)sulfonium trifluoromethanesulfonate, heptafluoropropanesulfonate or nonafluorobutanesulfonate, and di(1-naphthyl)phenylsulfonium trifluoromethanesulfonate, heptafluoropropanesulfonate or nonafluorobutanesulfonate. Furthermore, onium salts in which the anion portion of the above onium salts have been substituted with methanesulfonate, n-propanesulfonate, n-butanesulfonate, or n-octanesulfonate can also be used.

Furthermore, onium salt-based acid generators in which the anion portion within the above general formulas (b-1) and (b-2) has been substituted with an anion portion represented by a general formula (b-3) or (b-4) shown below (and in which the cation portion is the same as that shown in (b-1) or (b-2)) can also be used.

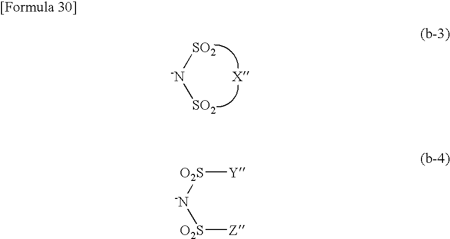

[wherein, X″ represents an alkylene group of 2 to 6 carbon atoms in which at least one hydrogen atom has been substituted with a fluorine atom; and Y″ and Z″ each represent, independently, an alkyl group of 1 to 10 carbon atoms in which at least one hydrogen atom has been substituted with a fluorine atom]

The group X″ is a straight-chain or branched alkylene group in which at least one hydrogen atom has been substituted with a fluorine atom, and the number of carbon atoms within the alkylene group is typically within a range from 2 to 6, preferably from 3 to 5, and is most preferably 3.

Y″ and Z″ each represent, independently, a straight-chain or branched alkyl group in which at least one hydrogen atom has been substituted with a fluorine atom, and the number of carbon atoms within the alkyl group is typically within a range from 1 to 10, preferably from 1 to 7, and is most preferably from 1 to 3.

Within the above ranges for the numbers of carbon atoms, lower numbers of carbon atoms within the alkylene group X″ or the alkyl groups Y″ and Z″ are preferred for reasons including better solubility within the resist solvent.

Furthermore, in the alkylene group X″ or the alkyl groups Y″ and Z″, the larger the number of hydrogen atoms that have been substituted with fluorine atoms, the stronger the acid becomes, and the transparency relative to high energy light beams of 200 nm or less or electron beams also improves favorably. The fluorine atom proportion within the alkylene group or alkyl groups, namely the fluorination ratio, is preferably within a range from 70 to 100%, and even more preferably from 90 to 100%, and perfluoroalkylene or perfluoroalkyl groups in which all of the hydrogen atoms have been substituted with fluorine atoms are the most desirable.

In the present description, the term “oxime sulfonate-based acid generator” describes a compound that contains at least one group represented by a general formula (B-1) shown below, and generates acid upon irradiation. These types of oxime sulfonate-based acid generators are widely used within chemically amplified resist compositions, and any of these conventional compounds can be used.

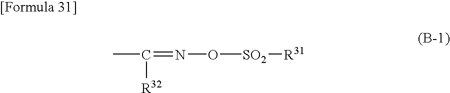

(In the formula (B-1), R³¹ and R³² each represent, independently, an organic group.)

The organic groups R³¹ and R³² preferably include carbon atoms, and may also include atoms other than carbon atoms (such as hydrogen atoms, oxygen atoms, nitrogen atoms, sulfur atoms, and halogen atoms (such as fluorine atoms or chlorine atoms)).

The organic group of R³¹ is preferably a straight-chain, branched or cyclic alkyl group or aryl group. These alkyl groups or aryl groups may also include a substituent group. There are no particular restrictions on such substituent groups, and suitable examples include a fluorine atom or a straight-chain, branched or cyclic alkyl group of 1 to 6 carbon atoms. Here, the expression “include a substituent group” means that either a portion of, or all of the hydrogen atoms of the alkyl group or aryl group are substituted with substituent groups.

The alkyl group preferably contains from 1 to 20 carbon atoms, even more preferably from 1 to 10 carbon atoms, even more preferably from 1 to 8 carbon atoms, even more preferably from 1 to 6 carbon atoms, and most preferably from 1 to 4 carbon atoms. Furthermore, alkyl groups that are partially or completely halogenated (hereafter also referred to as haloalkyl groups) are preferred. A partially halogenated alkyl group is an alkyl group in which a portion of the hydrogen atoms have been substituted with halogen atoms, whereas a completely halogenated alkyl group is an alkyl group in which all of the hydrogen atoms have been substituted with halogen atoms. Examples of the halogen atoms include fluorine atoms, chlorine atoms, bromine atoms or iodine atoms, although fluorine atoms are particularly desirable. In other words, the haloalkyl group is preferably a fluoroalkyl group.

The aryl group preferably contains from 4 to 20 carbon atoms, even more preferably from 4 to 10 carbon atoms, and most preferably from 6 to 10 carbon atoms. Aryl groups that are partially or completely halogenated are preferred. A partially halogenated aryl group is an aryl group in which a portion of the hydrogen atoms have been substituted with halogen atoms, whereas a completely halogenated aryl group is an aryl group in which all of the hydrogen atoms have been substituted with halogen atoms.

As the group R³¹, an alkyl group of 1 to 4 carbon atoms containing no substituent groups, or a fluoroalkyl group of 1 to 4 carbon atoms is the most desirable.

The organic group of R³² is preferably a straight-chain, branched or cyclic alkyl group or aryl group, or a cyano group. Examples of suitable alkyl groups and aryl groups for R³² include the same alkyl groups and aryl groups described above in relation to R³¹.

As the group R³², a cyano group, an alkyl group of 1 to 8 carbon atoms containing no substituent groups, or a fluoroalkyl group of 1 to 8 carbon atoms is the most desirable.

Particularly preferred oxime sulfonate-based acid generators include the compounds represented by the general formulas (B-2) and (B-3) shown below.

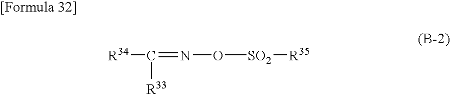

[In the formula (B-2), R³³ represents a cyano group, an alkyl group containing no substituent groups, or a haloalkyl group; R34 represents an aryl group; R³⁵ represents an alkyl group containing no substituent groups, or a haloalkyl group.]

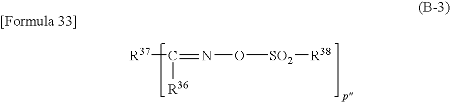

[In the formula (B-3), R³⁶ represents a cyano group, an alkyl group containing no substituent groups, or a haloalkyl group; R³⁷ represents a bivalent or trivalent aromatic hydrocarbon group; R³⁸ represents an alkyl group containing no substituent groups, or a haloalkyl group; p″ is either 2 or 3.]

In the above general formula (B-2), the alkyl group containing no substituent groups or haloalkyl group represented by R³³ preferably contains from 1 to 10 carbon atoms, even more preferably from 1 to 8 carbon atoms, and most preferably from 1 to 6 carbon atoms.

The group R³³ is preferably a haloalkyl group, and even more preferably a fluoroalkyl group.

In the fluoroalkyl group of R³³, at least 50% of the hydrogen atoms of the alkyl group are preferably fluorinated, and this ratio is even more preferably 70% or higher, and is most preferably 90% or higher.

The aryl group represented by R³⁴ is preferably a group in which one hydrogen atom has been removed from an aromatic hydrocarbon ring, such as a phenyl group, biphenyl group, fluorenyl group, naphthyl group, anthracyl group or phenanthryl group, or a heteroaryl group in which a portion of the carbon atoms that constitute the ring structure within one of the above groups have been substituted with a hetero atom such as an oxygen atom, sulfur atom or nitrogen atom. Of these possibilities, a fluorenyl group is particularly preferred.

The aryl group of R³⁴ may include a substituent group such as an alkyl group, haloalkyl group or alkoxy group of 1 to 10 carbon atoms. The alkyl group or haloalkyl group substituent groups preferably contain from 1 to 8 carbon atoms, and even more preferably from 1 to 4 carbon atoms. Furthermore, the haloalkyl group is preferably a fluoroalkyl group.

The alkyl group containing no substituent groups or haloalkyl group represented by R³⁵ preferably contains from 1 to 10 carbon atoms, even more preferably from 1 to 8 carbon atoms, and most preferably from 1 to 6 carbon atoms.

The group R³⁵ is preferably a haloalkyl group, and is preferably a partially or completely fluorinated alkyl group.

In the fluoroalkyl group of R³⁵, at least 50% of the hydrogen atoms of the alkyl group are preferably fluorinated, and groups in which 70% or more, and even more preferably 90% or more, of the hydrogen atoms are fluorinated are particularly desirable as they increase the strength of the acid that is generated. Completely fluorinated alkyl groups in which 100% of the hydrogen atom have been substituted with fluorine atoms are the most desirable.

In the above general formula (B-3), examples of the alkyl group containing no substituent groups or haloalkyl group represented by R³⁶ include the same alkyl groups containing no substituent groups and haloalkyl groups described above for the group R³³

Examples of the bivalent or trivalent aromatic hydrocarbon group represented by R³⁷ include groups in which a further one or two hydrogen atoms respectively are removed from an aryl group of the aforementioned group R³⁴.

Examples of the alkyl group containing no substituent groups or haloalkyl group represented by R³⁸ include the same alkyl groups containing no substituent groups and haloalkyl groups described above for the group R³⁵.

p″ is preferably 2.

Specific examples of suitable oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)-benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Furthermore, the oxime sulfonate-based acid generators disclosed in Japanese Unexamined Patent Application, First Publication No. Hei 09-208554 (formula 18 to formula 19 in paragraphs [0012] to [0014]), and the oxime sulfonate-based acid generators disclosed in WO2004/074242A2 (Examples 1 to 40 on pages 65 through 85) can also be used favorably.

Further examples of preferred compounds include those shown below.

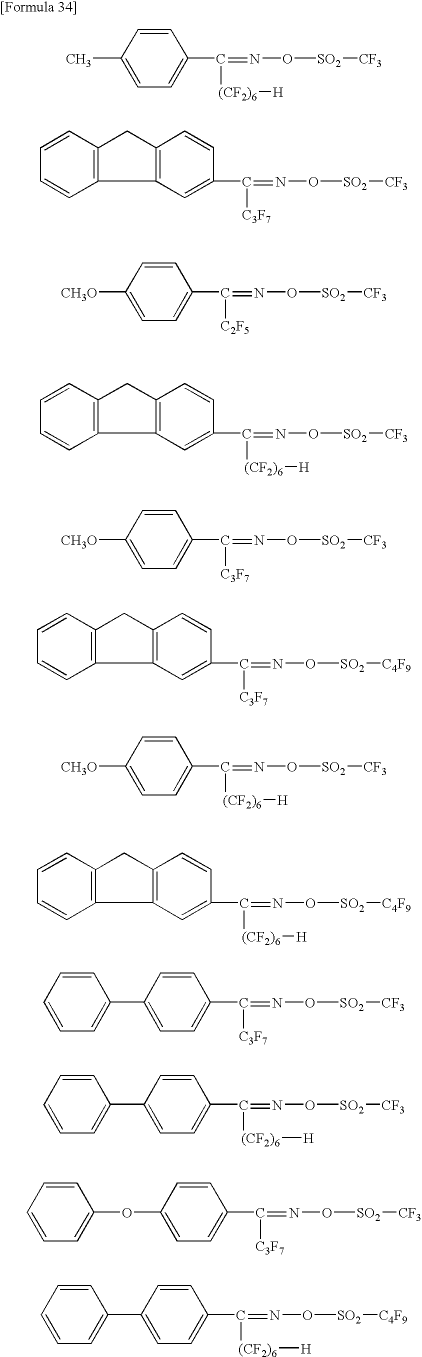

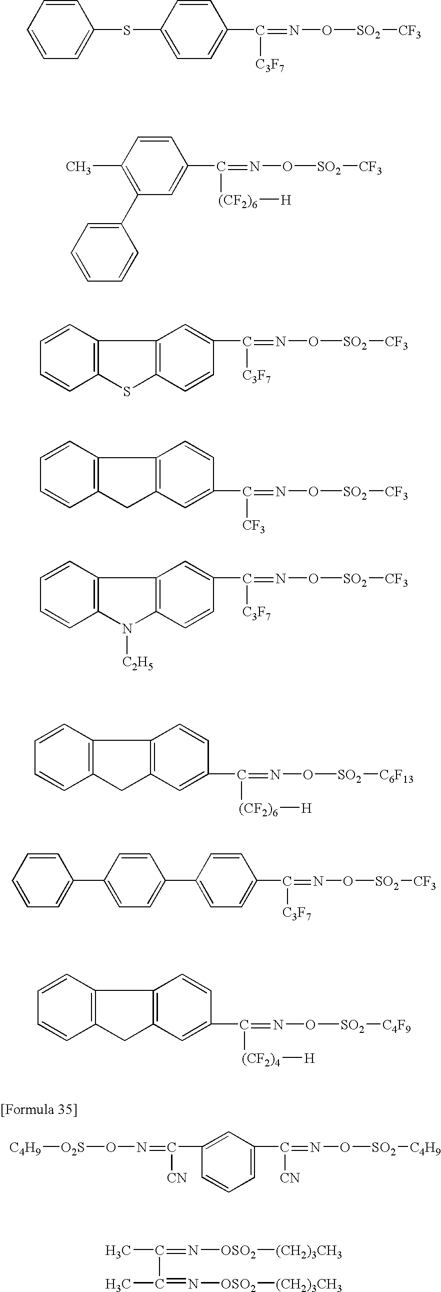

Of the compounds exemplified above, the four compounds shown below are particularly desirable.

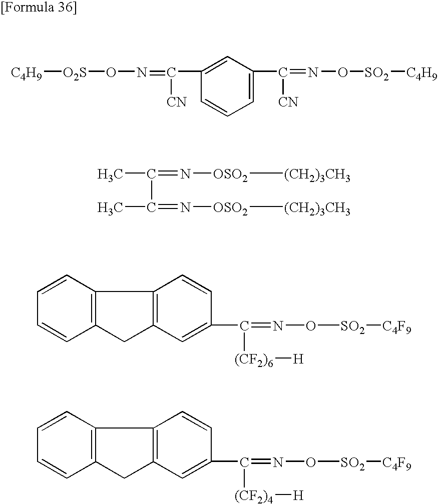

Of the various diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(ecyclohexylsulfonyl)diazomethane, and bis(2,4-dimethylphenylsulfonyl)diazomethane.

Furthermore, the diazomethane-based acid generators disclosed in Japanese Unexamined Patent Application, First Publication No. Hei 11-035551, Japanese Unexamined Patent Application, First Publication No. Hei 11-035552, and Japanese Unexamined Patent Application, First Publication No. Hei 11-035573 can also be used favorably.

Furthermore, specific examples of poly(bis-sulfonyl)diazomethanes include the structures disclosed in Japanese Unexamined Patent Application, First Publication No. Hei 11-322707, such as 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane.

As the component (B), any one of the above acid generators may be used alone, or a combination of two or more different acid generators may be used.

In the present invention, as the component (B), the use of an onium salt having a fluorinated alkylsulfonate ion as the anion is preferred. Specific examples include triphenylsulfonium nonafluorobutanesulfonate and (4-methylphenyl)diphenylsulfonium trifluoromethanesulfonate.

The quantity of the component (B) within a preferred positive resist composition of the present invention is typically within a range from 0.5 to 30 parts by weight, and preferably from 1 to 15 parts by weight, per 100 parts by weight of the component (A). Ensuring a quantity within this range enables satisfactory pattern formation to be conducted. Furthermore, a uniform solution is obtained, and the storage stability is also favorable, both of which are desirable.

### <Component (D)>

In a preferred positive resist composition of the present invention, in order to improve the resist pattern shape and the post exposure stability of the latent image formed by the pattern-wise exposure of the resist layer, a nitrogen-containing organic compound (D) (hereafter referred to as the component (D)) may also be added as an optional component.

A multitude of these components (D) have already been proposed, and any of these known compounds can be used, although a cyclic amine or an aliphatic amine, and particularly a secondary aliphatic amine or tertiary aliphatic amine is preferred.

Examples of these aliphatic amines include amines in which at least one hydrogen atom of ammonia (NH₃) has been substituted with an alkyl group or hydroxyalkyl group of 1 to 12 carbon atoms (that is, alkylamines or alkyl alcohol amines). Specific examples of these aliphatic amines include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine, and tri-n-dodecylamine; and alkyl alcohol amines such as diethanolamine, triethanolamine, diisopropanolamine, triisopropanolamine, di-n-octanolamine, and tri-n-octanolamine.

Of these, alkyl alcohol amines and trialkylamines are preferred, and alkyl alcohol amines are the most desirable. Amongst the various alkyl alcohol amines, triethanolamine and triisopropanolamine are the most preferred.

Examples of the cyclic amines include heterocyclic compounds containing a nitrogen atom as the hetero atom. These heterocyclic compounds may be either monocyclic compounds (aliphatic monocyclic amines) or polycyclic compounds (aliphatic polycyclic amines).

Specific examples of aliphatic monocyclic amines include piperidine and piperazine.

As the aliphatic polycyclic amine, compounds of 6 to 10 carbon atoms are preferred, and specific examples include 1,5-diazabicyclo[4.3.0]-5-nonene, 1,8-diazabicyclo[5.4.0]-7-undecene, hexamethylenetetramine, and 1,4-diazabicyclo[2.2.2]octane.

These compounds may be used either alone, or in combinations of two or more different compounds.

In the present invention, of the various possibilities, the use of an alkyl alcohol amine as the component (D) is preferred. A specific examples is triethanolamine.

The component (D) is typically used in a quantity within a range from 0.01 to 5.0 parts by weight per 100 parts by weight of the component (A).

### <Optional Components>

In a preferred positive resist composition of the present invention, in order to prevent deterioration in the sensitivity, and improve the resist pattern shape and the post exposure stability of the latent image formed by the pattern-wise exposure of the resist layer, an organic carboxylic acid, or a phosphorus oxo acid or derivative thereof (E) (hereafter referred to as the component (E)) may also be added as an optional component.

Examples of suitable organic carboxylic acids include malonic acid, citric acid, malic acid, succinic acid, benzoic acid, and salicylic acid.

Examples of suitable phosphorus oxo acids or derivatives thereof include phosphoric acid or derivatives thereof such as esters, including phosphoric acid, di-n-butyl phosphate and diphenyl phosphate; phosphonic acid or derivatives thereof such as esters, including phosphonic acid, dimethyl phosphonate, di-n-butyl phosphonate, phenylphosphonic acid, diphenyl phosphonate, and dibenzyl phosphonate; and phosphinic acid or derivatives thereof such as esters, including phosphinic acid and phenylphosphinic acid, and of these, phosphonic acid is particularly preferred.

The component (E) is typically used in a quantity within a range from 0.01 to 5.0 parts by weight per 100 parts by weight of the component (A).

Other miscible additives may also be added to a preferred positive resist composition of the present invention according to need, and examples include additive resins for improving the properties of the resist film, surfactants for improving the coating properties, dissolution inhibitors, plasticizers, stabilizers, colorants, halation prevention agents, and dyes.

### <Component (S)>

The resist composition of the present invention is produced by dissolving the base material components described above in an organic solvent (S) (hereafter referred to as the component (S)).

The component (S) contains ethyl lactate (EL) and an antioxidant, and the concentration of this antioxidant within the component (S) is 10 ppm or greater.

There are no particular restrictions on the antioxidant, and examples include radical scavengers such as hindered amine-based compounds and hindered phenol-based compounds; peroxide decomposers such as phosphorus-based compounds and sulfur-based compounds; and ultraviolet absorbers such as benzophenone-based compounds, salicylate-based compounds, and benzotriazole-based compounds. Of these, in terms of the effects obtained for the present invention, radical scavengers are preferred, and hindered phenol-based compounds are particularly desirable, including compounds such as 2,6-di-ten-butylphenol, 2-tert-butyl-4-methoxyphenol, 2,4-dimethyl-6-tert-butylphenol, 2,6-di-tert-butyl-4-methylphenol and 2,6-di-tert-butyl-4-ethylphenol. Of these compounds, 2,6-di-tert-butyl-4-methylphenol (BHT) is the most preferred.

The concentration of the antioxidant within the component (S) must be 10 ppm or greater, is preferably within a range from 10 to 300 ppm, even more preferably from 10 to 250 ppm, even more preferably from 12 to 200 ppm, and is most preferably from 15 to 150 ppm. Ensuring that the concentration of the antioxidant is at least 10 ppm enables the effects of the present invention to be achieved.

The quantity of ethyl lactate (EL) within the component (S) is preferably at least 10% by weight, even more preferably 20% by weight or greater. The quantity of the ethyl lactate (EL) within the component (S) may be 100% by weight, but other solvents may be combined with the ethyl lactate in order to adjust the solubility of the component (A) and the like or alter other properties, and in such cases, the upper limit for the quantity of ethyl lactate (EL) is preferably not more than 90% by weight. If the quantity of ethyl lactate is greater than the lower limit of the above range, then even at a quantity where the dimensions of the resist pattern would normally be prone to variation over time, the effects of the present invention are still readily attainable.

In those cases where the component (S) also includes an organic solvent (S2) described below besides the ethyl lactate (EL), the quantity range described above for the ethyl lactate (EL) also includes those cases where the antioxidant is incorporated within the ethyl lactate.

Moreover, those cases where the quantity of ethyl lactate (EL) represents 100% by weight of the component (S) refer to cases where the antioxidant is simply added to the ethyl lactate.

In the present invention, the component (S) may also include an organic solvent (S2) (hereafter referred to as the component (S2)) besides the ethyl lactate. As described above, including the component (S2) enables the solubility of the component (A) and the like, or other properties to be adjusted.

As the component (S2), one or more solvents selected from known materials used as the solvents for conventional chemically amplified resists can be used.

Examples include lactones such as γ-butyrolactone; ketones such as acetone, methyl ethyl ketone, cyclohexanone, methyl n-amyl ketone, methyl isoamyl ketone and 2-heptanone; polyhydric alcohols such as ethylene glycol, diethylene glycol, propylene glycol and dipropylene glycol, and derivatives thereof; polyhydric alcohol derivatives including compounds with an ester linkage such as ethylene glycol monoacetate, diethylene glycol monoacetate, propylene glycol monoacetate and dipropylene glycol monoacetate, and compounds with an ether linkage including monoalkyl ethers such as the monomethyl ether, monoethyl ether, monopropyl ether or monobutyl ether, or the monophenyl ether of any of the above polyhydric alcohols or the above compounds with an ester linkage; cyclic ethers such as dioxane; esters such as methyl lactate, methyl acetate, ethyl acetate, butyl acetate, methyl pyruvate, ethyl pyruvate, methyl methoxypropionate, and ethyl ethoxypropionate; and aromatic organic solvents such as anisole, ethyl benzyl ether, cresyl methyl ether, diphenyl ether, dibenzyl ether, phenetole, butyl phenyl ether, ethylbenzene, diethylbenzene, amylbenzene, isopropylbenzene, toluene, xylene, cymene, and mesitylene.

Of these solvents, propylene glycol monomethyl ether acetate (PGMEA) and propylene glycol monomethyl ether (PGME) are preferred, and PGMEA is particularly desirable.

In terms of factors such as the solubility of the component (A) and the like, and the controllability of other properties, the quantity of the component (S2) within the component (S) is preferably at least 10% by weight, even more preferably at least 50% by weight, and is most preferably 60% by weight or greater. The upper limit for the quantity of the component (S2) is preferably not more than 90% by weight.

Furthermore, a mixed solvent of EL and PGMEA is particularly preferred as the combination of organic solvents within the component (S). In this case, the weight ratio between the former and latter components is preferably within a range from 1:9 to 9:1, even more preferably from 2:8 to 8:2, and is most preferably from 2:8 to 5:5.

There are no particular restrictions on the quantity used of the component (S), which can be set in accordance with the coating film thickness required, at a concentration that enables favorable application of the composition to a substrate or the like. Typically, the quantity of the component (S) is set so that the solid fraction concentration of the resist composition is within a range from 2 to 20% by weight, and preferably from 5 to 15% by weight.

### <<Process for Producing Resist Composition>>

A process for producing a resist composition according to the present invention is a process that includes the steps of preparing an organic solvent (S) using ethyl lactate that contains an antioxidant, so that the concentration of the antioxidant within the organic solvent (S) is 10 ppm or greater, and dissolving the above base material components in the organic solvent (S).

The resist composition of the present invention can be produced, for example, in the manner described below.

First, the ethyl lactate containing the antioxidant is mixed with the other organic solvent (S2) where required, and an organic solvent (S) is prepared such that the concentration of the antioxidant within the organic solvent (S) is 10 ppm or greater.

The base material components described above are then dissolved in this organic solvent (S) to produce the resist composition. For example, in the case of a chemically amplified resist composition, the aforementioned component (A), a commonly employed component (B), a component (D) if required, and any optional components are mixed together and dissolved in the organic solvent (S) to prepare the resist composition.

This process enables the production of a resist composition that exhibits favorable dimensional stability of the resist pattern.

The ethyl lactate containing the antioxidant is preferably prepared by adding the antioxidant to the ethyl lactate during storage of the ethyl lactate, and adding the antioxidant to the ethyl lactate soon after the production of the ethyl lactate is particularly desirable. This yields further improvements in the effects of the present invention.

The nature of the antioxidant, ethyl lactate and the organic solvent (S2), and the quantities of the other organic solvent (S2) and the ethyl lactate containing the antioxidant within the component (S) are all as described above in the section entitled

### <<Resist Composition>>.

In the present invention, the quantity of the antioxidant added to the ethyl lactate is adjusted such that following preparation of the organic solvent (S), the concentration of the antioxidant within the organic solvent (S) is 10 ppm or greater.

Here, the expression “concentration of the antioxidant” refers to the concentration of all of the antioxidant that exists within the organic solvent (S).

In those cases where the antioxidant is added to the other organic solvent (S2) besides the ethyl lactate, the quantity should be adjusted so that the concentration within the resulting organic solvent (S) of the combined total of the antioxidant contained within the ethyl lactate and the antioxidant contained within the organic solvent (S2) is 10 ppm or greater. This antioxidant concentration is preferably within a range from 10 to 300 ppm, even more preferably from 10 to 250 ppm, even more preferably from 12 to 200 ppm, and is most preferably from 15 to 150 ppm. Ensuring that the concentration of the antioxidant is at least 10 ppm enables the effects of the present invention to be achieved.

The resist composition of the present invention is a resist composition prepared by dissolution in an organic solvent that includes ethyl lactate, and has the effects of suppressing variations in the dimensions of the resist pattern caused by storage of the resist composition, and providing favorable dimensional stability. The reasons for these effects are not entirely clear, but are thought to be as follows.

In a resist composition prepared by dissolution in an organic solvent containing ethyl lactate, if a resist pattern is formed following storage of the resist pattern for a certain period of time, then the dimensions of the resist pattern are prone to variation as a result of the storage of the resist composition, meaning the dimensional stability of the resist pattern is unsatisfactory. It is thought that this observation is due to the effects of decomposition products generated by decomposition of the ethyl lactate over time.

This decomposition of the ethyl lactate over time is thought to be due to the generation of radicals caused by heat, light and O₂ or the like during storage of the resist composition, with these radicals then acting as the origins for the formation of new radicals, causing a chain-like oxidative degradation.

In the present invention, it is thought that by incorporating at least 10 ppm of an antioxidant within the organic solvent that includes the ethyl lactate, any radicals generated during storage of the resist composition can be satisfactorily captured, thereby suppressing the oxidative degradation of the ethyl lactate. It is believed that, as a result, the aforementioned decomposition over time of the ethyl lactate is inhibited, thereby improving the dimensional stability of the resist pattern.

Furthermore, in the present invention, adding the antioxidant to the organic solvent (and particularly the ethyl lactate) used in the resist composition prior to storage of the resist composition is particularly effective. It is thought that this enables an enhancement of the suppression effect on the oxidative degradation of the ethyl lactate, thereby better inhibiting the decomposition over time of the ethyl lactate. It is surmised that by using this ethyl lactate for which decomposition has been inhibited in a resist composition, variations in the dimensions of the resist pattern caused by storage of the resist composition can be suppressed, resulting in an improvement in the dimensional stability of the pattern.

### (Method of Forming Resist Pattern)

In the present invention, the method of forming a resist pattern can be conducted, for example, in the manner described below.

Namely, the resist composition described above is first applied to a substrate such as a silicon wafer using a spinner or the like, a prebake (post-applied bake (PAB)) is then conducted under temperature conditions of 80 to 150° C., for a period of 40 to 120 seconds, and preferably for 60 to 90 seconds, and following selective exposure of the thus obtained film with an ArF exposure apparatus or the like, by irradiating ArF excimer laser light through a desired mask pattern, PEB (post exposure baking) is conducted under temperature conditions of 80 to 150° C., for a period of 40 to 120 seconds, and preferably for 60 to 90 seconds. Subsequently, developing is conducted using an alkali developing liquid such as a 0.1 to 10% by weight aqueous solution of tetramethylammonium hydroxide. In this manner, a resist pattern that is faithful to the mask pattern can be obtained.

An organic or inorganic anti-reflective film may also be provided between the substrate and the applied layer of the resist composition.

There are no particular restrictions on the wavelength used for the exposure, and an ArF excimer laser, KrF excimer laser, F₂ excimer laser, or other radiation such as EUV (extreme ultra violet), VUV (vacuum ultra violet), EB (electron beam), X-ray or soft X-ray radiation can be used. A resist composition according to the present invention is particularly effective for use with an ArF excimer laser.

### EXAMPLES

As follows is a more detailed description of the present invention based on a series of examples, although the present invention is in no way limited by the examples presented below.

### [Evaluation of Ethyl Lactate (EL) Over Time]

The following evaluation over time was conducted using ethyl lactate (EL) and 2,6-di-tert-butyl-4-methylphenol (BHT) as the antioxidant.

The BHT was added to samples of the ethyl lactate (EL) in sufficient quantity to prepare EL samples with BHT concentration levels of 0, 30 and 300 ppm respectively. The EL samples with these BHT concentration levels were then stored for 3 months, either in a freezer (−20° C.) or at a temperature of 40° C.

Following the 3-month storage period, each of the stored EL samples with the various BHT concentration levels was measured for EL purity (% by weight), and the concentration of the by-products acetic acid (ppm) and pyruvic acid (ppm) were also measured using the method described below. The results are shown in Table 1.

### (Measurement Methods)

The EL purity was measured by gas chromatography (product name: GC-17A, manufactured by Shimadzu Corporation), whereas the concentration of acetic acid and the concentration of pyruvic acid were measured by ion chromatography (product name: DX500, manufactured by DIONEX Corporation).

TABLE 1

| | | | | Acetic acid | Pyruvic acid |
|---|---|---|---|---|---|
| | BHT concentration | Storage | EL purity | concentration | concentration |
| | within EL (ppm) | temperature | (% by weight) | (ppm) | (ppm) |
| EL-1 | 0 | Freezer | 99.9 | 43.1 | 1.6 |
| EL-2 | 30 | | 99.9 | 36.7 | 0.0 |
| EL-3 | 300 | | 99.9 | 37.4 | 0.0 |
| EL-4 | 0 | 40° C. | 99.8 | 79.3 | 2.6 |
| EL-5 | 30 | | 99.9 | 46.5 | 0.0 |
| EL-6 | 300 | | 99.9 | 40.1 | 0.0 |

From Table 1 it is clear that of the samples EL-1 to EL-3 that were stored at freezer temperature, the samples EL-2 and EL-3 in which the BHT concentration was 30 and 300 ppm respectively had lower concentration levels of the by-products acetic acid and pyruvic acid than the sample EL-1 in which the BHT concentration was 0. In other words, decomposition over time (oxidative degradation) was suppressed.

Similarly, of the samples EL-4 to EL-6 that were stored at a temperature of 40° C., the samples EL-5 and EL-6 in which the BHT concentration was 30 and 300 ppm exhibited a suppressed level of decomposition over time (oxidative degradation) compared with the sample EL-4 in which the BHT concentration was 0.

Furthermore, it was also clear that the samples EL-4 to EL-6 that had been stored at 40° C. had undergone more decomposition over time (oxidative degradation) than the samples EL-1 to EL-3 that were stored in a freezer.

### [Preparation of Positive Resist Composition Solutions]

Using the above ethyl lactate samples EL-1 to EL-6 that had been stored for 3 months, the components shown in Table 2 were mixed together and dissolved, yielding a series of positive resist composition solutions.

TABLE 2

| | (A) | (B) | | (D) | (S) | |
|---|---|---|---|---|---|---|
| Comparative | (A)-1 | (B)-1 | (B)-2 | (D)-1 | EL-1 | (S)-1 |
| example 1 | [100] | [2.0] | [0.6] | [0.30] | [320] | [480] |
| Example 1 | (A)-1 | (B)-1 | (B)-2 | (D)-1 | EL-2 | (S)-1 |
| | [100] | [2.0] | [0.6] | [0.30] | [320] | [480] |
| Example 2 | (A)-1 | (B)-1 | (B)-2 | (D)-1 | EL-3 | (S)-1 |
| | [100] | [2.0] | [0.6] | [0.30] | [320] | [480] |
| Comparative | (A)-1 | (B)-1 | (B)-2 | (D)-1 | EL-4 | (S)-1 |
| example 2 | [100] | [2.0] | [0.6] | [0.30] | [320] | [480] |
| Example 3 | (A)-1 | (B)-1 | (B)-2 | (D)-1 | EL-5 | (S)-1 |
| | [100] | [2.0] | [0.6] | [0.30] | [320] | [480] |
| Example 4 | (A)-1 | (B)-1 | (B)-2 | (D)-1 | EL-6 | (S)-1 |
| | [100] | [2.0] | [0.6] | [0.30] | [320] | [480] |

The meanings of the abbreviations used in Table 2 are as shown below. The numerical values within the brackets [ ] represent blend quantities (parts by weight).

(A)-1: a resin represented by the formula shown below.
l:m:n=4/4/2 (molar ratio), Mw=11,000, Mw/Mm=1.55.

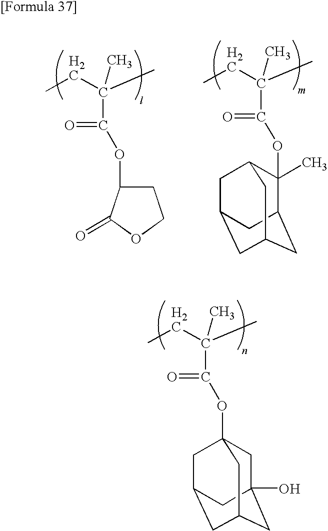

(B)-1: triphenylsulfonium nonafluorobutanesulfonate
(B)-2: 4-methylphenyldiphenylsulfonium trifluoromethanesulfonate
(D)-1: triethanolamine
(S)-1: PGMEA (PGMEA with a BHT concentration of 10 ppm was used)

### [Evaluation of Resist Pattern Dimensional Stability]

Each of the positive resist composition solutions prepared above was stored for one week, either in a freezer (−20° C.) or at a temperature of 40° C.

Following storage for one week, each of the positive resist composition solutions was used to form a resist pattern in accordance with the method described below.

An organic anti-reflective film composition ARC-29 (a product name, manufactured by Brewer Science Ltd.) was applied to the surface of an 8-inch silicon wafer, and the composition was then baked and dried on a hotplate at 225° C. for 60 seconds, thereby forming an organic anti-reflective film with a film thickness of 77 nm, and completing preparation of a substrate.

The prepared positive resist composition solution was then applied uniformly to the surface of this substrate using a spinner, and was then prebaked (PAB) and dried on a hotplate for 90 seconds at the temperature shown in Table 3, thereby forming a resist layer with a film thickness of 400 nm.

Subsequently, the resist layer was selectively irradiated through a mask using an ArF exposure apparatus (wavelength: 193 nm) NSR-S302 (manufactured by Nikon Corporation, NA (numerical aperture)=0.60, σ=0.75).

A PEB treatment was then conducted for 90 seconds at the temperature shown in Table 3, and the resist layer was developed for 30 seconds at 23° C. in a developing liquid (a 2.38% by weight aqueous solution of tetramethylammonium hydroxide), and was then rinsed with pure water and shaken dry, thus forming a line and space (1:1) resist pattern.

### <Dimensional Stability of Resist Pattern>

A resist pattern with a line width of 160 nm and a pitch of 320 nm was formed, and the line width of the pattern was measured using a measuring SEM (product name: S-9220, manufactured by Hitachi, Ltd.).

The difference was calculated between the line width of the resist pattern formed using the resist composition solution that had been stored at 40° C., and the line width of the resist pattern formed using the resist composition solution that had been stored in a freezer, and this value was used as the quantity of dimensional variation (nm) in the resist pattern over time. The results are shown in Table 3.

TABLE 3

| | | | BHT concentration | Resist pattern dimension (nm) | | |
|---|---|---|---|---|---|---|
| | PAB | PEB | within component | Storage at | Storage in | 40° C. − |
| | (° C.) | (° C.) | (S) (ppm) | 40° C. | freezer | freezer |
| Comparative | 130 | 130 | 6 | 161.1 | 156.7 | 4.3 |
| example 1 | | | | | | |
| Example 1 | 130 | 130 | 18 | 155.0 | 155.0 | 0.0 |
| Example 2 | 130 | 130 | 126 | 154.6 | 154.7 | −0.1 |
| Comparative | 130 | 130 | 6 | 167.5 | 158.8 | 8.7 |
| example 2 | | | | | | |
| Example 3 | 130 | 130 | 18 | 156.0 | 155.0 | 1.0 |
| Example 4 | 130 | 130 | 126 | 155.0 | 154.8 | 0.2 |

From Table 3 it is evident that the resist compositions of the examples 1 to 4 according to the present invention exhibit a smaller variation over time in the dimension of the resist pattern than the resist compositions of the comparative examples 1 and 2, indicating a more favorable dimensional stability for the resist pattern.

### INDUSTRIAL APPLICABILITY

The present invention is able to provide a resist composition dissolved in an organic solvent that includes ethyl lactate, and a process for producing the resist composition, wherein dimensional variation in the resist pattern caused by storage of the resist composition is inhibited.

1. A resist composition comprising an organic solvent (S), and a base material component dissolved in said organic solvent (S), wherein said organic solvent (S) comprises ethyl lactate and an antioxidant, and a concentration of said antioxidant within said organic solvent (S) is 10 ppm or greater.

2. A resist composition according to claim 1, which is a chemically amplified resist composition.

3. A resist composition according to claim 1, wherein said antioxidant comprises 2,6-di-tert-butyl-4-methylphenol.

4. A resist composition according to claim 2, wherein said antioxidant comprises 2,6-di-tert-butyl-4-methylphenol.

5. A process for producing a resist composition, comprising the steps of: preparing an organic solvent (S) using ethyl lactate that comprises an antioxidant, so that a concentration of said antioxidant within said organic solvent (S) is 10 ppm or greater, and dissolving a base material component in said organic solvent (S).

6. A process for producing a resist composition according to claim 5, wherein said antioxidant comprises 2,6-di-tert-butyl-4-methylphenol.
